(19) United States
(12) Patent Application Publication
(10) Pub. No.: US 2024/0130184 A1
(43) Pub. Date: Apr. 18, 2024

(54) DISPLAY PANEL AND ELECTRONIC APPARATUS

(71) Applicant: Samsung Display Co., Ltd., Yongin-si (KR)

(72) Inventors: Dongsoo Kim, Yongin-si (KR); Joongsoo Moon, Yongin-si (KR); Hansol Kim, Yongin-si (KR); Jaeyong Lee, Yongin-si (KR); Sunbaek Hong, Yongin-si (KR)

(21) Appl. No.: 18/473,848

(22) Filed: Sep. 25, 2023

(30) Foreign Application Priority Data
Oct. 12, 2022 (KR) 10-2022-0130924

(51) Int. Cl. H10K 59/131; H10K 59/122

(52) U.S. Cl. CPC H10K 59/131; H10K 59/122

(57) ABSTRACT

A display panel includes: a first sub-pixel circuit at a first display area, and including: a first transistor; a storage capacitor; and a second transistor; an organic insulating layer on the first transistor and the second transistor; a first light-emitting diode at the first display area, and electrically connected to the first sub-pixel circuit; a second light-emitting diode at a second display area including a transmission area; a bank layer having a first opening, and a second opening; at least one line overlapping with a first electrode of the first light-emitting diode and the first opening of the bank layer; and a conductive pattern layer at the second display area and overlapping with a first electrode of the second light-emitting diode and the second opening of the bank layer. The conductive pattern layer is located at a same layer as that of the at least one line.

### CROSS-REFERENCE TO RELATED APPLICATION

This application claims priority to and the benefit of Korean Patent Application No. 10-2022-0130924, filed in the Korean Intellectual Property Office on Oct. 12, 2022, the entire disclosure of which is incorporated by reference herein.

### BACKGROUND

### 1. Field

One or more embodiments of the present disclosure relate to a display panel, and an electronic apparatus including the display panel.

### 2. Description of the Related Art

Display panels visually display data. Recently, display panels have been widely used. Because the thickness and weight of the display panels have been reduced, the use of the display panels has widened.

As measures for expanding an area occupied by a display area, and adding various functions at the same time, research into display panels has continued to add a function, other than a display function, to the inside of or within the display area.

The above information disclosed in this Background section is for enhancement of understanding of the background of the present disclosure, and therefore, it may contain information that does not constitute prior art.

### SUMMARY

One or more embodiments of the present disclosure are directed to a display panel including a transmission area in a display area, and an electronic apparatus including the display panel.

The above and additional aspects and features of the present disclosure will be set forth, in part, in the description that follows, and in part, will be apparent from the description, or may be learned by practicing one or more of the presented embodiments of the present disclosure.

According to one or more embodiments of the present disclosure, a display panel includes: a first sub-pixel circuit at a first display area, and including: a first transistor including a first semiconductor layer and a first gate electrode; a storage capacitor; and a second transistor including a second semiconductor layer and a second gate electrode; an organic insulating layer on the first transistor and the second transistor; a first light-emitting diode at the first display area, and electrically connected to the first sub-pixel circuit, the first light-emitting diode including a first electrode on the organic insulating layer; a second light-emitting diode at a second display area at least partially surrounded by the first display area, and including a first electrode on the organic insulating layer, the second display area including a transmission area; a bank layer having a first opening overlapping with the first electrode of the first light-emitting diode, and a second opening overlapping with the first electrode of the second light-emitting diode; at least one line overlapping with the first electrode of the first light-emitting diode and the first opening of the bank layer; and a conductive pattern layer at the second display area and overlapping with the first electrode of the second light-emitting diode and the second opening of the bank layer. The at least one line includes at least one of a driving power line, a data connection line, or a data line, and the conductive pattern layer is located at a same layer as that of the at least one line.

In an embodiment, the display panel may further include a lower organic insulating layer under the organic insulating layer, and the conductive pattern layer and the at least one line may be located between the lower organic insulating layer and the organic insulating layer.

In an embodiment, the display panel may further include: a second sub-pixel circuit at a third display area between the first display area and the second display area, and electrically connected to the second light-emitting diode; and a conductive bus line extending towards the second display area at the third display area to electrically connect the second sub-pixel circuit to the second light-emitting diode.

In an embodiment, the conductive bus line may be located at a same layer as that of any one of the first gate electrode, an electrode of the storage capacitor, or the second gate electrode.

In an embodiment, the conductive pattern layer may include a plurality of conductive lines overlapping with the second opening of the bank layer, and an extension direction of each of the plurality of conductive lines may be the same as an extension direction of the at least one line overlapping with the first opening of the bank layer.

In an embodiment, the at least one line may include a plurality of data lines, and a data connection line, and a first distance between two adjacent conductive lines selected from among the plurality of conductive lines may be the same as a second distance between two adjacent lines selected from among the plurality of data lines and the data connection line.

In an embodiment, the plurality of conductive lines may be integrally connected to a connection conductive line crossing the plurality of conductive lines.

In an embodiment, the at least one line may include a connection portion of a plurality of driving power lines that are physically connected to each other, and a shape or an area in which the second opening of the bank layer overlaps with the conductive pattern layer may be the same as a shape or an area in which the first opening of the bank layer overlaps with the connection portion of the plurality of driving power lines.

In an embodiment, in a plan view, a shape in which the second opening of the bank layer overlaps with the conductive pattern layer may be the same as a shape in which the first opening of the bank layer overlaps with a portion of the at least one line.

In an embodiment, the display panel may further include a conductive line at the second display area, and the conductive line may overlap with each of the first electrode of the second light-emitting diode, the second opening of the bank layer, and the conductive pattern layer.

In an embodiment, the display panel may further include an additional second light-emitting diode at the second display area, and configured to emit the same color of light as that of the second light-emitting diode, and the conductive line may include a connection line electrically connecting the second light-emitting diode to the additional second light-emitting diode.

In an embodiment, the organic insulating layer may have a first via contact hole for electrically connecting the first sub-pixel circuit to the first electrode of the first light-emitting diode, and a second via contact hole for electrically connecting the conductive pattern layer to the first electrode of the second light-emitting diode, and each of the first via contact hole and the second via contact hole may overlap with the bank layer.

In an embodiment, an angle between a first virtual line extending from a center of the first opening of the bank layer towards the first via contact hole and a virtual reference line passing the center of the first opening in a first direction may be the same as an angle between a second virtual line extending from a center of the second opening of the bank layer towards the second via contact hole and a virtual reference line passing the center of the second opening in the first direction.

According to one or more embodiments of the present disclosure, an electronic apparatus includes: a display panel including: a first display area; and a second display area at least partially surrounded by the first display area, and including a transmission area; and a component under the display panel, and corresponding to the second display area. The display panel includes: a first sub-pixel circuit at the first display area, and including: a first transistor including a first semiconductor layer and a first gate electrode; a storage capacitor; and a second transistor including a second semiconductor layer and a second gate electrode; an organic insulating layer above the first transistor and the second transistor; a first light-emitting diode at the first display area, and electrically connected to the first sub-pixel circuit, the first light-emitting diode including a first electrode on the organic insulating layer; a second light-emitting diode at the second display area, and including a first electrode on the organic insulating layer; a bank layer having a first opening overlapping with the first electrode of the first light-emitting diode, and a second opening overlapping with the first electrode of the second light-emitting diode; at least one line overlapping with the first electrode of the first light-emitting diode and the first opening of the bank layer; and a conductive pattern layer at the second display area, and overlapping with the first electrode of the second light-emitting diode and the second opening of the bank layer. The at least one line includes at least one of a driving power line, a data connection line, or a data line, and the conductive pattern layer is located at a same layer as that of the at least one line.

In an embodiment, the component may include a camera or a sensor.

In an embodiment, the display panel may further include a lower organic insulating layer under the organic insulating layer, and the conductive pattern layer and the at least one line may be located between the lower organic insulating layer and the organic insulating layer.

In an embodiment, the display panel may further include: a second sub-pixel circuit at a third display area between the first display area and the second display area, and electrically connected to the second light-emitting diode; and a conductive bus line extending towards the second display area at the third display area to electrically connect the second sub-pixel circuit to the second light-emitting diode.

In an embodiment, the conductive bus line may be located at a same layer as that of any one of the first gate electrode, an electrode of the storage capacitor, or the second gate electrode.

In an embodiment, the conductive pattern layer may include a plurality of conductive lines overlapping with the second opening of the bank layer, and an extension direction of each of the plurality of conductive lines may be the same as an extension direction of the at least one line overlapping with the first opening of the bank layer.

In an embodiment, the at least one line of the display panel may include a plurality of data lines and data connection lines, and a first distance between two adjacent conductive lines selected from among the plurality of conductive lines may be the same as a second distance between two adjacent lines selected from among the plurality of data lines and data connection lines.

In an embodiment, the plurality of conductive lines may be integrally connected to a connection conductive line crossing the plurality of conductive lines.

In an embodiment, the at least one line may include a connection portion of a plurality of driving power lines that are physically connected to each other, and a shape or an area in which the second opening of the bank layer overlaps with the conductive pattern layer may be the same as a shape or an area in which the first opening of the bank layer overlaps with the connection portion of the plurality of driving power lines.

In an embodiment, in a plan view, a shape in which the second opening of the bank layer overlaps with the conductive pattern layer may be the same as a shape in which the first opening of the bank layer overlaps with a portion of the at least one line.

In an embodiment, the display panel may further include a conductive line at the second display area, and the conductive line may overlap with each of the first electrode of the second light-emitting diode, the second opening of the bank layer, and the conductive pattern layer.

In an embodiment, the display panel may further include an additional second light-emitting diode at the second display area, and configured to emit the same color of light as that of the second light-emitting diode, and the conductive line may include a connection line electrically connecting the second light-emitting diode to the additional second light-emitting diode.

In an embodiment, the organic insulating layer may have a first via contact hole for electrically connecting the first sub-pixel circuit to the first electrode of the first light-emitting diode, and a second via contact hole for electrically connecting the conductive pattern layer to the first electrode of the second light-emitting diode, and an angle between a first virtual line extending from a center of the first opening of the bank layer towards the first via contact hole and a virtual reference line passing the center of the first opening in a first direction may be the same as an angle between a second virtual line extending from a center of the second opening of the bank layer towards the second via contact hole and a virtual reference line passing the center of the second opening in the first direction.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a schematic perspective view of an electronic apparatus according to an embodiment;

FIG. 2 is a schematic cross-sectional view of an electronic apparatus according to an embodiment;

FIG. 3 is a schematic plan view of a display panel according to an embodiment;

FIG. 4 is a schematic equivalent circuit diagram of a sub-pixel circuit of a display panel, and a light-emitting diode electrically connected to the sub-pixel circuit, according to an embodiment;

FIG. 5 is a plan view of sub-pixels arranged in a display area of a display panel, according to an embodiment;

FIG. 6A is a plan view of a first display area of a display panel, according to an embodiment;

FIG. 6B is a cross-sectional view of a first display area of a display panel, according to an embodiment;

FIG. 7A is a plan view of a second display area and a third display area of a display panel, according to an embodiment;

FIG. 7B is a cross-sectional view of a second display area and a third display area of a display panel, according to an embodiment;

FIG. 8 is a plan view of a portion of a first display area of a display panel, according to an embodiment;

FIG. 9 is a plan view of a portion of a second display area of a display panel, according to an embodiment;

FIG. 10 is a cross-sectional view of a display panel taken along the line X-X′ of FIG. 9, according to an embodiment;

FIG. 11 is a cross-sectional view of a display panel taken along the line XI-XI′ of FIG. 9, according to an embodiment;

FIG. 12 is a cross-sectional view of a display panel taken along the line XII-XII′ of FIG. 9, according to an embodiment;

FIG. 13A is a plan view of a second display area of a display panel, according to an embodiment;

FIG. 13B is a cross-sectional view of a second display area taken along the line XIII-XIII′ of FIG. 13A; and

FIGS. 14A and 14B are schematic plan views of a first conductive pattern layer and a third conductive pattern layer, according to one or more embodiments.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

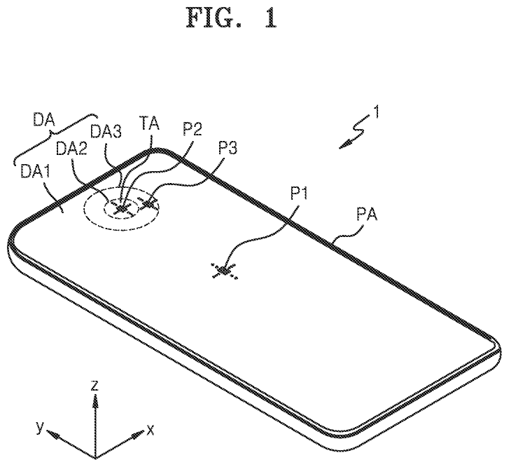

FIG. 1 is a schematic perspective view of an electronic apparatus according to an embodiment.

Referring to FIG. 1, an electronic apparatus 1 may include a display area DA, and a peripheral area PA on an outer side of the display area DA. In the display area DA, images may be displayed through sub-pixels. The peripheral area PA may be a non-display area where no images are displayed, and is located on the outer side of the display area DA, such as to entirely or substantially entirely surround (e.g., around a periphery of) the display area DA. Drivers or the like configured to provide electrical signals or power to the display area DA may be arranged at (e.g., in or on) the peripheral area PA. A pad that may be electrically connected to an electronic component or a printed circuit board may be arranged at (e.g., in or on) the peripheral area PA.

Hereinafter, the electronic apparatus 1 will be described in more detail in the context of a smartphone for convenience, but the present disclosure is not limited thereto. The electronic apparatus 1 may be applied to various suitable products and devices, for example, such as a portable electric apparatus such as a mobile phone, a smartphone, a tablet Personal Computer (PC), a mobile communication terminal, a personal digital assistant, an e-book terminal, a Portable Multimedia Player (PMP), a navigation device, or an Ultra Mobile PC (UMPC), a television (TV), a laptop, a monitor, a billboard, an Internet of Things (IoT) device, and/or the like. Also, in an embodiment, the electronic apparatus 1 may be used in a wearable device, such as a smartwatch, a watch phone, an eyewear display, or a head-mounted display (HMD). Also, in an embodiment, the electronic apparatus 1 may be used as a display screen in an instrument cluster of a vehicle, a Center Information Display (CID) mounted on a center fascia or a dashboard of a vehicle, a room mirror display replacing a side-view mirror of a vehicle, or a car headrest monitor provided for the rear-seat entertainment of a vehicle.

The display area DA may include a first display area DA1, a second display area DA2, and a third display area DA3. In the display area DA, images may be displayed by using sub-pixels that are two-dimensionally arranged. The sub-pixels may include first sub-pixels P1 arranged at (e.g., in or on) the first display area DA1, second sub-pixels P2 arranged at (e.g., in or on) the second display area DA2, and third sub-pixels P3 arranged at (e.g., in or on) the third display area DA3.

The first display area DA1 may occupy most of the display area DA, which may indicate that an area of the first display area DA1 is greater than or equal to about 50% of an area of the display area DA.

The second display area DA2 may be at least partially surrounded (e.g., around a periphery thereof) by the first display area DA1. In an embodiment, the second display area DA2 may be located inside (e.g., within) the first display area DA1, and may be entirely surrounded (e.g., around a periphery thereof) by the first display area DA1.

The third display area DA3 may be located between the first display area DA1 and the second display area DA2. The third display area DA3 may at least partially surround (e.g., around a periphery of) the second display area DA2. In an embodiment, the third display area DA3 may entirely surround (e.g., around a periphery of) the second display area DA2, and may be entirely surrounded (e.g., around a periphery thereof) by the first display area DA1.

The second display area DA2 and the third display area DA3 may each have an area less than that of the first display area DA1. In an embodiment, as illustrated in FIG. 1, each of the second display area DA2 and the third display area DA3 may have a circular shape. In another embodiment, each of the second display area DA2 and the third display area DA3 may have a polygonal shape, such as a rectangular or substantially rectangular shape.

FIG. 1 illustrates that the second display area DA2 and the third display area DA3 are located at the center of an upper portion of the display area DA (in the +y direction) having a rectangular or substantially rectangular shape when viewed in a direction perpendicular to or substantially perpendicular to an upper surface of the electronic apparatus 1 (e.g., in the z direction), but the present disclosure is not limited thereto. The second display area DA2 and the third display area DA3 may be arranged on, for example, an upper right portion or an upper left portion of the display area DA.

The second display area DA2 may realize images by using the second sub-pixels P2, and light or sound may penetrate a portion of the second display area DA2 between the second sub-pixels P2. Hereinafter, an area where light or sound may penetrate is referred to as a transmission area TA. In other words, the second display area DA2 may include a transmission area TA between the second sub-pixels P2.

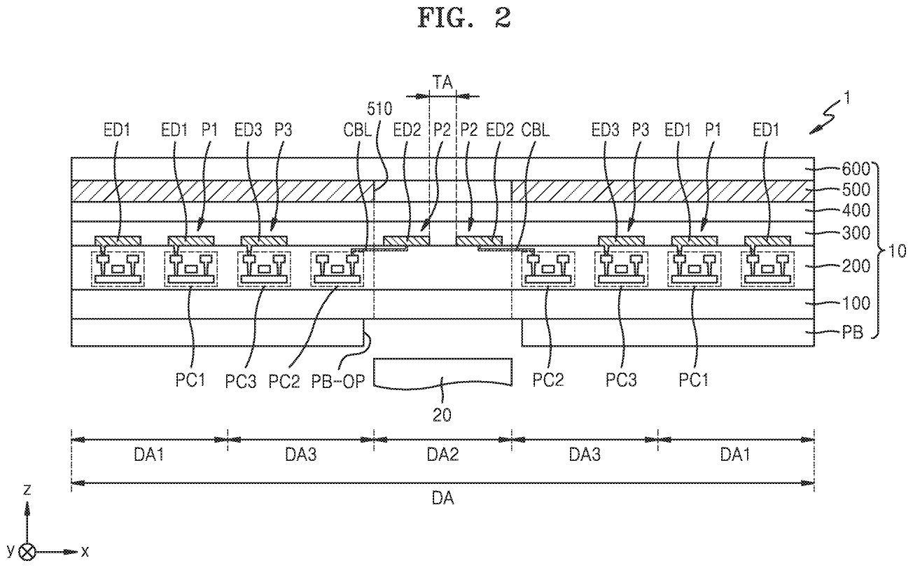

FIG. 2 is a schematic cross-sectional view of an electronic apparatus according to an embodiment.

Referring to FIG. 2, the electronic apparatus 1 may include a display panel 10, and a component 20 overlapping with the display panel 10. The component 20 may be arranged in the second display area DA2.

The component 20 may be an electronic component that uses light or sound. For example, an electronic component may be a sensor (e.g., a proximity sensor), which measures a distance, a sensor for recognizing a body part of a user (e.g., fingerprints, the iris, the face, and/or the like), a small lamp for outputting light, an image sensor (e.g., a camera) for capturing images, or the like. An electronic component that uses light may use light in various suitable wavelength bands, for example, such as visible rays, infrared rays, ultraviolet rays, and/or the like. An electronic component that uses sound may use ultrasound or sound in a different frequency band.

The second display area DA2 may include the transmission area TA where light and/or sound output to the outside from the component 20 or traveling towards the component 20 from the outside may penetrate. In an embodiment, the transmission area TA may be an area where light may penetrate, and may correspond to an area located between the second sub-pixels P2. When light penetrates through the second display area DA2 including the transmission area TA, the transmittance of the light may be greater than or equal to about 10%, for example, such as 25%, 40%, 50%, 85%, or 90%.

The first sub-pixel P1, the second sub-pixel P2, and the third sub-pixel P3 described above with reference to FIG. 1 may respectively emit light by using light-emitting diodes, and the light-emitting diodes may be arranged at (e.g., in or on) the display area DA of the display panel 10. As used in the present specification, a light-emitting diode corresponding to the first sub-pixel P1 of the first display area DA1 is referred to as a first light-emitting diode ED1, a light-emitting diode corresponding to the second sub-pixel P2 of the second display area DA2 is referred to as a second light-emitting diode ED2, and a light-emitting diode corresponding to the third sub-pixel P3 of the third display area DA3 is referred to as a third light-emitting diode ED3. The first light-emitting diode to the third light-emitting diode ED1 to ED3 may be disposed above a substrate 100.

The substrate 100 may include an insulating material, such as a glass material or a polymer resin, and a protective film PB may be disposed on a rear surface of the substrate 100. The substrate 100 may be a rigid substrate, or a flexible substrate that is bendable, foldable, or rollable. The protective film PB may include an opening PB-OP in the second display area DA2 to improve the transmittance of the transmission area TA.

A display layer 200 including sub-pixel circuits is arranged on the substrate 100. The first light-emitting diode ED1 is arranged at (e.g., in or on) the first display area DA1, and is electrically connected to a first sub-pixel circuit PC1 arranged at (e.g., in or on) the first display area DA1. The first sub-pixel circuit PC1 may include transistors, and a storage capacitor electrically connected to the transistors.

The second light-emitting diode ED2 is arranged at (e.g., in or on) the second display area DA2. The second light-emitting diode ED2 is electrically connected to a second sub-pixel circuit PC2, and the second sub-pixel circuit PC2 is not arranged at (e.g., in or on) the second display area DA2 to improve the transmittance of the transmission area TA included in the second display area DA2, and to increase a light transmission area of the transmission area TA.

The second sub-pixel circuit PC2 may be arranged at (e.g., in or on) an area different from the second display area DA2, for example, such as at (e.g., in or on) the third display area DA3. In another embodiment, the second sub-pixel circuit PC2 may be arranged at (e.g., in or on) the peripheral area PA (e.g., see FIG. 1), but for convenience, hereinafter, the second sub-pixel circuit PC2 may be described in more detail as being arranged at (e.g., in or on) the third display area DA3.

The second light-emitting diode ED2 may be electrically connected to the second sub-pixel circuit PC2 through a conductive bus line CBL. The conductive bus line CBL may electrically connect the second sub-pixel circuit PC2 at (e.g., in or on) the third display area DA3 to the second light-emitting diode ED2 at (e.g., in or on) the second display area DA2.

The third light-emitting diode ED3 is arranged at (e.g., in or on) the third display area DA3, and is electrically connected to a third sub-pixel circuit PC3 arranged at (e.g., in or on) the third display area DA3. The third sub-pixel circuit PC3 may include transistors, and a storage capacitor electrically connected to the transistors.

The first light-emitting diode to the third light-emitting diode ED1 to ED3 are light-emitting elements for emitting suitable colors (e.g., certain or predetermined colors) of light, and may include organic light-emitting diodes. In another embodiment, the first light-emitting diode to the third light-emitting diode ED1 to ED3 may include inorganic light-emitting diodes, or light-emitting diodes including quantum dots.

The first light-emitting diode to the third light-emitting diode ED1 to ED3 may be covered by an encapsulation layer 300. The encapsulation layer 300 may include a thin-film encapsulation layer including an inorganic encapsulation layer including an inorganic insulating material, and an organic encapsulation layer including an organic insulating material. In an embodiment, the encapsulation layer 300 may include a first inorganic encapsulation layer and a second inorganic encapsulation layer, and an organic encapsulation layer therebetween.

In another embodiment, the encapsulation layer 300 may be an encapsulation substrate, such as a glass substrate. A sealant including a frit and/or the like may be arranged between the substrate 100 and the encapsulation substrate. The sealant may be arranged at (e.g., in or on) the peripheral area PA, and may extend to surround (e.g., around) outer edges of the display area DA, and thus, may prevent or substantially prevent moisture from penetrating the first light-emitting diode to the third light-emitting diode ED1 to ED3 through (e.g., along) a lateral direction.

An input detection layer 400 may be formed on the encapsulation layer 300. The input detection layer 400 may obtain coordinate information according to an external input, for example, such as a touch event from an object, such as a finger or a stylus pen. The input detection layer 400 may include a touch electrode, and trace lines connected to the touch electrode. The input detection layer 400 may detect an external input in a mutual cap manner and/or a self-cap manner.

An optical functional layer 500 may include a reflection prevention layer. The reflection prevention layer may decrease a reflectivity of light (e.g., external light) that is incident toward the display panel 10 from the outside through a cover window 600. The reflection prevention layer may include a retarder and a polarizer. When the optical functional layer 500 includes a polarizer, the optical functional layer 500 may include an opening 510 located in the second display area DA2, and thus, the transmittance of the transmission area TA may be improved.

In another embodiment, the reflection prevention layer may include a black matrix and color filters. The color filters may be arranged by considering the colors of light respectively emitted from the first light-emitting diode to the third light-emitting diode ED1 to ED3. When the optical functional layer 500 includes the black matrix and the color filters, a light-transmissive material may be arranged at a location corresponding to the transmission area TA.

In another embodiment, the reflection prevention layer may include a destructive interference structure. The destructive interference structure may include a first reflection layer and a second reflection layer disposed at (e.g., in or on) different layers from each other. First reflection light and second reflection light, which are respectively reflected from the first reflection layer and the second reflection layer, may destructively interfere with each other, and the reflectivity of the external light may decrease accordingly.

The cover window 600 may be disposed on the optical functional layer 500. The cover window 600 may be adhered to the optical functional layer 500 by an adhesive layer, such as an optically clear adhesive, disposed between the cover window 600 and the optical functional layer 500. The cover window 600 may include a glass material or a plastic material. The plastic material may include polyethersulfone, polyacrylate, polyetherimide, polyethylene naphthalate, polyethylene terephthalate, polyphenylene sulfide, polyarylate, polyimide, polycarbonate, cellulose acetate propionate, or the like.

The cover window 600 may include a flexible cover window. For example, the cover window 600 may include a polyimide cover window or an ultra-thin glass cover window.

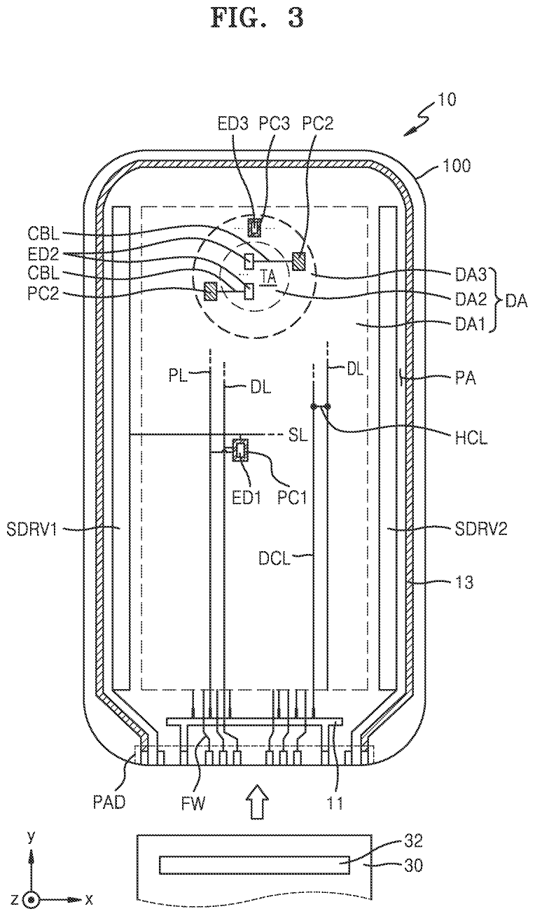

FIG. 3 is a schematic plan view of a display panel according to an embodiment.

Referring to FIG. 3, the display panel 10 may include the display area DA and the peripheral area PA. The display area DA may include the first display area to the third display area DA1, DA2, and DA3. The display area DA, for example, the first display area to the third display area DA1, DA2, and DA3, may correspond to an image surface of the display panel 10.

Light-emitting diodes are arranged at (e.g., in or on) the first display area to the third display area DA1, DA2, and DA3, and sub-pixel circuits respectively and electrically connected to the light-emitting diodes are arranged at (e.g., in or on) the first display area DA1 and the third display area DA3, but not at (e.g., in or on) the second display area DA2. For example, first sub-pixel circuits PC1 electrically connected to the first light-emitting diodes ED1 may be arranged at (e.g., in or on) the first display area DA1, and second sub-pixel circuits PC2 and third sub-pixel circuits PC3 electrically connected to second sub-pixel circuits ED2 and the third light-emitting diodes ED3, respectively, may be arranged at (e.g., in or on) the third display area DA3. In other words, some of the sub-pixel circuits arranged at (e.g., in or on) the third display area DA3 (e.g., the second sub-pixel circuits PC2) may be electrically connected to the second light-emitting diodes ED2 arranged at (e.g., in or on) the second display area DA2, and others of the sub-pixel circuits arranged at (e.g., in or on) the third display area DA3 (e.g., the third sub-pixel circuits PC3) may be electrically connected to the third light-emitting diodes ED3 arranged at (e.g., in or on) the third display area DA3.

The first light-emitting diodes ED1 are arranged at (e.g., in or on) the first display area DA1. Light emitted from the first light-emitting diode ED1 may correspond to light from the first sub-pixel P1 described above with reference to FIG. 1, and the location of the first light-emitting diode ED1 may be that of the first sub-pixel P1. The first light-emitting diode ED1 may emit, for example, red light, green light, or blue light. The first sub-pixel circuit PC1 for driving the first light-emitting diode ED1 may be arranged at (e.g., in or on) the first display area DA1, and electrically connected to the first light-emitting diode ED1.

The first sub-pixel circuit PC1 is electrically connected to a scan line SL extending in a first direction (e.g., the x direction), and a data line DL extending in a second direction (e.g., the y direction). A first driving circuit SDRV1 and a second driving circuit SDRV2 configured to provide signals to the first sub-pixel circuits PC1 may be arranged at (e.g., in or on) the peripheral area PA.

Some of the data lines DL may receive data signals through fanout lines FW, and others may receive data signals through a fanout line FW, and a data connection line DCL connected to the fanout line FW. As shown in FIG. 3, for example, some data signals may be transmitted to other data lines DL through the fanout line FW, the data connection line DCL extending in the second direction (e.g., the y direction) and connected to the fanout line FW, and a horizontal connection line HCL extending in the first direction (e.g., the x direction) and connecting the data connection line DCL and the other data lines DL to each other. Because the data connection line DCL, the horizontal connection line HCL, and the other data lines DL are lines having the same signal (the data signal), the data connection line DCL and the horizontal connection line HCL may also be a kind of signal lines like the data lines DL.

The first driving circuit SDRV1 may be configured to provide a scan signal to the first sub-pixel circuits PC1 through the scan line SL. The second driving circuit SDRV2 may be arranged opposite to the first driving circuit SDRV1, with the first display area DA1 therebetween. Some of the first sub-pixel circuits PC1 at (e.g., in or on) the first display area DA1 may be electrically connected to the first driving circuit SDRV1, and others may be electrically connected to the second driving circuit SDRV2.

A pad PAD may be arranged on one side of the substrate 100. The pad PAD may not be covered by an insulating layer and may be exposed, and thus, may be connected to a circuit board 30. A control driver 32 may be arranged at (e.g., in or on) the circuit board 30.

The control driver 32 may generate control signals transmitted to the first driving circuit SDRV1 and the second driving circuit SDRV2. The control driver 32 may include a data driving circuit, and the data driving circuit may generate data signals. The generated data signals may be transmitted to the first sub-pixel circuits PC1 through the fanout line FW arranged at (e.g., in or on) the peripheral area PA, and the data line DL connected to the fanout line FW. In other embodiments, the data driving circuit may be arranged at (e.g., in or on) the peripheral area PA of the substrate 100.

The second light-emitting diode ED2 is arranged at (e.g., in or on) the second display area DA2. Light emitted from the second light-emitting diode ED2 may correspond to light from the second sub-pixel P2 described above with reference to FIG. 1, and the location of the second light-emitting diode ED2 may be that of the second sub-pixel P2. The second light-emitting diode ED2 may emit, for example, red light, green light, or blue light.

The transmission area TA may be arranged between the second light-emitting diodes ED2. In an embodiment, a portion of the second display area DA2, in which the second light-emitting diodes ED2 are not arranged, may be the transmission area TA. To increase an area of the transmission area TA and improve the transmittance, the second sub-pixel circuit PC2 for driving the second light-emitting diode ED2 may be arranged at (e.g., in or on) the third display area DA3 located on the outer side of the second display area DA2. Some of the second sub-pixel circuits PC2 may be arranged at (e.g., in or on) some portions of the third display area DA3 that are adjacent to an upper portion of the second display area DA2, and others thereof may be arranged at (e.g., in or on) some portions of the third display area DA3 that are adjacent to a lower portion of the second display area DA2.

The second sub-pixel circuit PC2 at (e.g., in or on) the third display area DA3 may be electrically connected to the second light-emitting diode ED2 at (e.g., in or on) the second display area DA2 through the conductive bus line CBL. For example, the second light-emitting diode ED2 may be electrically connected to the second sub-pixel circuit PC2 through the conductive bus line CBL extending in the first direction (e.g., the x direction).

The third light-emitting diode ED3 is arranged at (e.g., in or on) the third display area DA3. Light emitted from the third light-emitting diode ED3 may correspond to light from the third sub-pixel P3 described above with reference to FIG. 1, and the location of the third light-emitting diode ED3 may be that of the third sub-pixel P3. The third light-emitting diode ED3 may emit, for example, red light, green light, or blue light.

The third sub-pixel circuit PC3 for driving the third light-emitting diode ED3 is arranged at (e.g., in or on) the third display area DA3. The third sub-pixel circuit PC3 may be electrically connected to the third light-emitting diode ED3, and may drive the third light-emitting diode ED3.

The second sub-pixel circuit PC2 and the third sub-pixel circuit PC3 may be electrically connected to the first driving circuit SDRV1 and/or the second driving circuit SDRV2. At least any one of the second sub-pixel circuits PC2 and/or at least any one of the third sub-pixel circuits PC3 may share a scan line with at least any one of the first sub-pixel circuits PC1. At least any one of the second sub-pixel circuits PC2 and/or at least any one of the third sub-pixel circuits PC3 may share a data line with at least any one of the first sub-pixel circuits PC1.

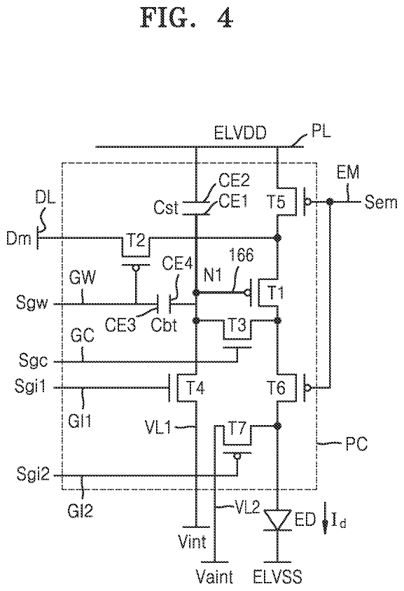

A driving voltage supply line 11 and a common voltage supply line 13 may be arranged at (e.g., in or on) the peripheral area PA. The driving voltage supply line 11 may be configured to apply a driving voltage to a sub-pixel circuit (e.g., each of the first sub-pixel circuit to the third sub-pixel circuit PC1, PC2, and PC3), and the common voltage supply line 13 may be configured to apply a common voltage ELVSS (see FIG. 4) to second electrodes (e.g., cathodes) of the light-emitting diodes (e.g., connected to the first sub-pixel circuit to the third sub-pixel circuit PC1, PC2, and PC3).

The driving voltage supply line 11 may be arranged between the pad PAD and one side of the display area DA. The common voltage supply line 13 may have a loop shape with one open side, and may partially surround (e.g., around a periphery of) the display area DA. The driving voltage supply line 11 may be electrically connected to a driving power line PL passing (e.g., extending across) the display area DA.

The first light-emitting diode to the third light-emitting diode ED1 to ED3, the first sub-pixel circuit to the third sub-pixel circuit PC1, PC2, and PC3, the pad PAD, the first driving circuit SDRV1, the second driving circuit SDRV2, the driving voltage supply line 11, and the common voltage supply line 13 are disposed above the substrate 100. A shape of the display panel 10 of FIG. 3 may be the same or substantially the same as that of the substrate 100. Therefore, when the display panel 10 includes the display area DA and the peripheral area PA, the substrate 100 includes the display area DA and the peripheral area PA.

FIG. 4 is a schematic equivalent circuit diagram of a sub-pixel circuit of a display panel, and a light-emitting diode electrically connected to the sub-pixel circuit, according to an embodiment. The sub-pixel circuit PC described in more detail with reference to FIG. 4 may correspond to any one of the first, second, and third sub-pixel circuits PC1, PC2, and PC3 that are described above with reference to FIG. 3, and the light-emitting diode ED of FIG. 4 may correspond to any one of the first, second, and third light-emitting diodes ED1, ED2, and ED3.

Referring to FIG. 4, the light-emitting diode ED may be electrically connected to the sub-pixel circuit PC. The sub-pixel circuit PC may include a first transistor T1 through a seventh transistor T7, a storage capacitor Cst, and a boost capacitor Cbt. In another embodiment, the sub-pixel circuit PC may not include the boost capacitor Cbt.

Some of the first transistor though the seventh transistor T1 through T7 may each be n-channel MOSFET (NMOS) transistors, and others thereof may each be p-channel MOSFET (PMOS) transistors. In an embodiment, as shown in FIG. 4, the third transistor T3 and the fourth transistor T4 may each be an NMOS transistor, and the others may each be a PMOS transistor. For example, the third transistor T3 and the fourth transistor T4 may each be an NMOS transistor including an oxide semiconductor material, and the others may each be a PMOS transistor including a silicon semiconductor material. In another embodiment, the third transistor T3, the fourth transistor T4, and the seventh transistor T7 may each be an NMOS transistor, and the others may each be a PMOS transistor.

The first transistor T1 to the seventh transistor T7, the storage capacitor Cst, and the boost capacitor Cbt may be connected to signal lines. The signal lines may include a scan line GW, an emission control line EM, a compensation gate line GC, a first initialization gate line GI1, a second initialization gate line GI2, and the data line DL. The sub-pixel circuits PC may be electrically connected to voltage lines, for example, such as the driving power line PL, a first initialization voltage line VL1, and a second initialization voltage line VL2.

The first transistor T1 may be a driving transistor. A first gate electrode of the first transistor T1 may be connected to the storage capacitor Cst. A first electrode of the first transistor T1 may be electrically connected to the driving power line PL through the fifth transistor T5, and a second electrode of the first transistor T1 may be electrically connected to a first electrode (e.g., an anode) of the light-emitting diode ED through the sixth transistor T6. One of the first electrode and the second electrode of the first transistor T1 may be a source electrode, and the other thereof may be a drain electrode. The first transistor T1 may be configured to provide a driving current Id to the light-emitting diode ED according to a switching operation of the second transistor T2.

The second transistor T2 may be a switching transistor. A second gate electrode of the second transistor T2 may be connected to the scan line GW, a first electrode of the second transistor T2 may be connected to the data line DL, a second electrode of the second transistor T2 may be connected to the first electrode of the first transistor T1, and electrically connected to the driving power line PL through the fifth transistor T5. One of the first electrode and the second electrode of the second transistor T2 may be a source electrode, and the other thereof may be a drain electrode. The second transistor T2 may be turned on in response to a scan signal Sgw transmitted through the scan line GW, and perform a switching operation to transmit a data signal Dm transmitted through the data line DL to the first electrode of the first transistor T1.

The third transistor T3 may be a compensation transistor configured to compensate for a threshold voltage of the first transistor T1. A third gate electrode of the third transistor T3 is connected to a compensation gate line GC. A first electrode of the third transistor T3 is connected to a lower electrode CE1 of the storage capacitor Cst and the first gate electrode of the first transistor T1 through a node connection line 166. The first electrode of the third transistor T3 may be connected to the fourth transistor T4. A second electrode of the third transistor T3 is connected to the second electrode of the first transistor T1, and electrically connected to the first electrode (e.g., the anode) of the light-emitting diode ED through the sixth transistor T6. One of the first electrode and the second electrode of the third transistor T3 may be a source electrode, and the other thereof may be a drain electrode.

The third transistor T3 is turned on in response to a compensation signal Sgc transmitted through the compensation gate line GC, and is electrically connected to the second electrode (e.g., a drain electrode) and the first gate electrode of the first transistor T1, and thus, diode-connects the first transistor T1.

The fourth transistor T4 may be a first initialization transistor configured to initialize the first gate electrode of the first transistor T1. A fourth gate electrode of the fourth transistor T4 is connected to the first initialization gate line GI1. A first electrode of the fourth transistor T4 is connected to the first initialization voltage line VL1. A second electrode of the fourth transistor T4 may be connected to the lower electrode CE1 of the storage capacitor Cst, the first electrode of the third transistor T3, and the first gate electrode of the first transistor T1. One of the first electrode and the second electrode of the fourth transistor T4 may be a source electrode, and the other thereof may be a drain electrode. The fourth transistor T4 may be turned on in response to a first initialization signal Sgi1 transmitted through the first initialization gate line GI1, and configured to transmit a first initialization voltage Vint to the first gate electrode of the first transistor T1, and thus, performing an initialization operation of initializing a voltage of the first gate electrode of the first transistor T1.

The fifth transistor T5 may be an operation control transistor. A fifth gate electrode of the fifth transistor T5 is connected to the emission control line EM. A first electrode of the fifth transistor T5 is connected to the driving power line PL, and a second electrode of the fifth transistor T5 is connected to the first electrode of the first transistor T1 and the second electrode of the second transistor T2. One of the first electrode and the second electrode of the fifth transistor T5 may be a source electrode, and the other thereof may be a drain electrode.

The sixth transistor T6 may be an emission control transistor. A sixth gate electrode of the sixth transistor T6 is connected to the emission control line EM. A first electrode of the sixth transistor T6 is connected to the second electrode of the first transistor T1 and the second electrode of the third transistor T3, and a second electrode of the sixth transistor t6 is electrically connected to a second electrode of the seventh transistor T7 and the first electrode (e.g., the anode) of the light-emitting diode ED. One of the first electrode and the second electrode of the sixth transistor T6 may be a source electrode, and the other thereof may be a drain electrode.

The fifth transistor T5 and the sixth transistor T6 may be concurrently (e.g., simultaneously or substantially simultaneously) turned on with each other in response to an emission control signal Sem transmitted through the emission control line EM, and are configured to transmit a driving voltage ELVDD to the light-emitting diode ED, so that the driving current Id flows in the light-emitting diode ED.

The seventh transistor T7 may be a second initialization transistor configured to initialize the first electrode (e.g., the anode) of the light-emitting diode ED. A seventh gate electrode of the seventh transistor T7 is connected to the second initialization gate line GI2. A first electrode of the seventh transistor T7 is connected to the second initialization voltage line VL2. The second electrode of the seventh transistor T7 is connected to the second electrode of the sixth transistor T6 and the first electrode (e.g., the anode) of the light-emitting diode ED. The seventh transistor T7 may be turned on in response to a second initialization signal Sgi2 transmitted through the second initialization gate line GI2, and configured to transmit a second initialization voltage Vaint to the first electrode (e.g., the anode) of the light-emitting diode ED, and thus, initializes the first electrode of the light-emitting diode ED.

In some embodiments, the second initialization gate line GI2 may be a next scan line. For example, the second initialization gate line GI2 connected to the seventh transistor T7 of the sub-pixel circuit PC arranged in an i^{th} row (where, i is a natural number greater than 0) may correspond to a scan line of the sub-pixel circuit PC arranged in an (i+1)^{th} row. In other embodiments, the second initialization gate line GI2 may be the emission control line EM. For example, the emission control line EM may be electrically connected to the fifth transistor T5, the sixth transistor T6, and the seventh transistor T7.

The storage capacitor Cst includes the lower electrode CE1 and an upper electrode CE2. The lower electrode CE1 of the storage capacitor Cst is connected to the first gate electrode of the first transistor T1, and the upper electrode CE2 of the storage capacitor Cst is connected to the driving power line PL. The storage capacitor Cst may store electric charges corresponding to a difference between the voltage of the first gate electrode of the first transistor T1 and the driving voltage ELVDD.

The boost capacitor Cbt includes a third electrode CE3 and a fourth electrode CE4. The third electrode CE3 may be connected to the second gate electrode of the second transistor T2 and the scan line GW, and the fourth electrode CE4 may be connected to the first electrode of the third transistor T3 and the node connection line 166. The boost capacitor Cbt may increase a voltage of the first node N1 when the scan signal Sgw provided to the scan line GW is turned off, and when the voltage of the first node N1 increases, a black gray scale may be clearly expressed.

The first node N1 may be a region where the first gate electrode of the first transistor T1, the first electrode of the third transistor T3, the second electrode of the fourth transistor T4, and the fourth electrode CE4 of the boost capacitor Cbt are connected to each other.

In an embodiment, FIG. 4 shows that the third transistor T3 and the fourth transistor T4 may each be an NMOS transistor, and the first transistor T1, the second transistor T2, and the fifth transistor T5 through the seventh transistor T7 may each be a PMOS transistor. The first transistor T1 directly affecting the brightness of the display apparatus is configured to include a semiconductor layer including polycrystalline silicon having high reliability, and thus, a high-resolution display apparatus may be realized.

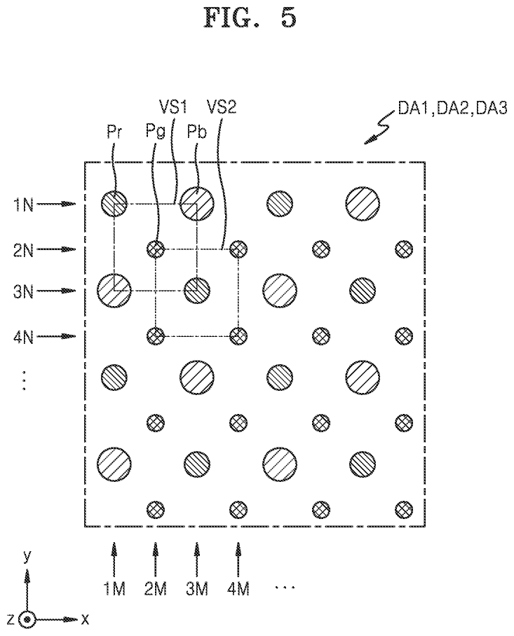

FIG. 5 is a plan view of sub-pixels arranged in a display area of a display panel, according to an embodiment.

Referring to FIG. 5, red sub-pixels Pr, green sub-pixels Pg, and blue sub-pixels Pb arranged at (e.g., in or on) the first display area to the third display area DA1, DA2, and DA3 may have the same or substantially the same arrangements with one another in a plane (e.g., in a plan view).

In some embodiments, the first display area to the third display area DA1, DA2, and DA3 may have the same or substantially the same resolution with each other. In other words, in the same or substantially the same sized area, the number and/or area of sub-pixel circuits at (e.g., in or on) the first display area DA1, the number and/or area of sub-pixel circuits at (e.g., in or on) the second display area DA2, and the number and/or area of sub-pixel circuits at (e.g., in or on) the third display area DA3 may be the same or substantially the same with each other.

Referring to FIG. 5, for example, the red sub-pixels Pr, the green sub-pixels Pg, and the blue sub-pixels Pb may be arranged in a diamond (e.g., a PENTILE®, a duly registered trademark of Samsung Display Co., Ltd.) form. In FIG. 5, the reference symbols 1N, 2N, 3N, 4N, . . . , respectively, indicate rows of sub-pixels, and the reference symbols 1M, 2M, 3M, 4M, . . . , respectively, indicate columns of sub-pixels. For example, the red sub-pixels Pr and the blue sub-pixels Pb are alternately arranged along a first row 1N. The green sub-pixels Pg are arranged at suitable intervals (e.g., certain or predetermined intervals) in a second row 2N adjacent to the first row 1N. The blue sub-pixels Pb and the red sub-pixels Pr are alternately arranged along a third row 3N adjacent to the second row 2N. The green sub-pixels Pg are arranged at suitable intervals (e.g., certain or predetermined intervals) in a fourth row 4N adjacent to the third row 3N. These sub-pixel arrangements are repeated. In an embodiment, the sizes (e.g., widths) of the blue sub-pixels Pb and the red sub-pixels Pr may be greater than those of the green sub-pixels Pg. The size (e.g., the width) of the blue sub-pixel Pb may be the same or substantially the same as or different from the size (e.g., the width) of the red sub-pixel Pr.

The red sub-pixels Pr and the blue sub-pixels Pb arranged in the first row 1N may be arranged alternately with the green sub-pixels Pg arranged in the second row 2N. Therefore, the red sub-pixels Pr and the blue sub-pixels Pb are alternately arranged along a first column 1M. The green sub-pixels Pg are arranged at suitable intervals (e.g., certain or predetermined intervals) in a second column 2M adjacent to the first column 1M. The blue sub-pixels Pb and the red sub-pixels Pr are alternately arranged along a third column 3M adjacent to the second column 2M. The green sub-pixels Pg are arranged at suitable intervals (e.g., certain or predetermined intervals) in a fourth column 4M adjacent to the third column 3M. These sub-pixel arrangements are repeated.

When the sub-pixel arrangements are expressed differently, it may be described that the red sub-pixels Pr are arranged on first and third vertices that face away from each other from among the vertices of a first virtual quadrangle VS1 of which a center point thereof is at a center point of the green sub-pixel Pg, and that the blue sub-pixels Pb are arranged on second and fourth vertices of the first virtual quadrangle VS1.

When the above sub-pixel arrangements are expressed differently, the green sub-pixels Pg are arranged respectively on the vertices of a second virtual quadrangle VS2 of which a center point thereof is at a center point of the red sub-pixel Pr or the blue sub-pixel Pb. The first virtual quadrangle VS1 and the second virtual quadrangle VS2 may have various suitable shapes, for example, such as a rectangle, a rhombus, a square, or the like.

The above sub-pixel arrangement is referred to as a diamond type arrangement (e.g., a PENTILE® arrangement), and may implement a high resolution with a smaller number of sub-pixels by performing rendering during which colors are expressed by sharing adjacent pixels.

FIG. 5 shows an example arrangement of a diamond type, but the present disclosure is not limited thereto. The red sub-pixels Pr, the green sub-pixels Pg, and the blue sub-pixels Pb may be arranged to have various suitable forms.

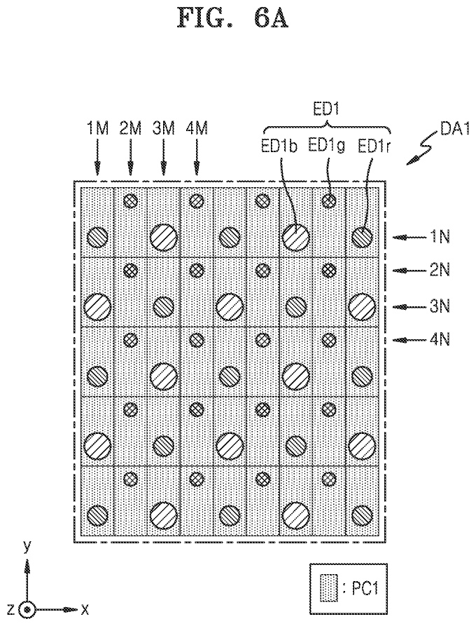

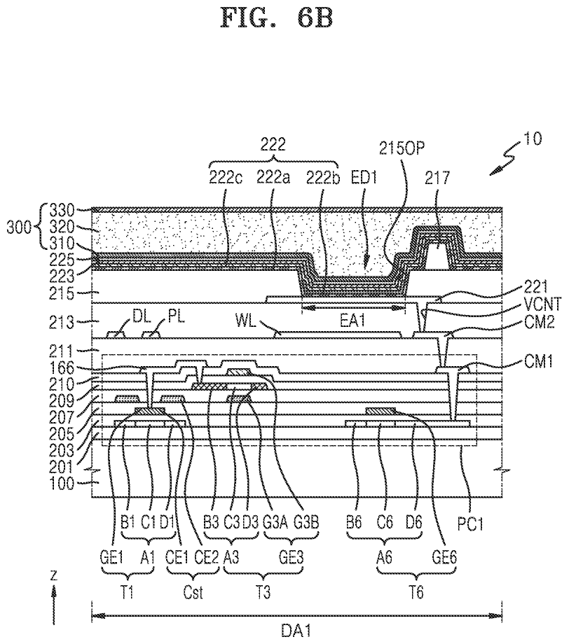

FIG. 6A is a plan view of a first display area of a display panel, according to an embodiment.

Referring to FIG. 6A, the first sub-pixel circuits PC1 may be arranged at (e.g., in or on) the first display area DA1 along the first direction (e.g., the x direction) and the second direction (e.g., the y direction). The first light-emitting diodes ED1 arranged at (e.g., in or on) the first display area DA1 may be arranged on the first sub-pixel circuits PC1. The first light-emitting diodes ED1 may include first red light-emitting diodes ED1r, first green light-emitting diodes ED1g, and first blue light-emitting diodes ED1b.

In the first display area DA1, the arrangements of the first red light-emitting diodes ED1r, the first green light-emitting diodes ED1g, and the first blue light-emitting diodes ED1b may be the same or substantially the same as the arrangements of the red sub-pixels Pr, the green sub-pixels Pg, and the blue sub-pixels Pb described above with reference to FIG. 5.

In the first display area DA1, the first red light-emitting diodes ED1r and the first blue light-emitting diodes ED1b may be alternately arranged along the first row 1N. The first green light-emitting diodes ED1g may be arranged at suitable intervals (e.g., certain or predetermined intervals) in the second row 2N adjacent to the first row 1N. The first blue light-emitting diodes ED1b and the first red light-emitting diodes ED1r may be alternately arranged along the third row 3N adjacent to the second row 2N. The first green light-emitting diodes ED1g may be arranged at suitable intervals (e.g., certain or predetermined intervals) in the fourth row 4N adjacent to the third row 3N.

The first red light-emitting diodes ED1r and the first blue light-emitting diodes ED1b arranged along the first row 1N and the first green light-emitting diodes ED1g arranged in the second row 2N may be alternately arranged with each other. Therefore, in the display area DA, the first red light-emitting diodes ED1r and the first blue light-emitting diodes ED1b may be alternately arranged along the first column 1M. The first green light-emitting diodes ED1g may be arranged at suitable intervals (e.g., certain or predetermined intervals) in the second column 2M adjacent to the first column 1M. The first blue light-emitting diodes ED1b and the first red light-emitting diodes ED1r may be alternately arranged along the third column 3M adjacent to the second column 2M. The first green light-emitting diodes ED1g may be arranged at suitable intervals (e.g., certain or predetermined intervals) in the fourth column 4M adjacent to the third column 3M. These arrangements may be repeated.

FIG. 6B is a cross-sectional view of a first display area of a display panel, according to an embodiment.

Referring to FIG. 6B, the first sub-pixel circuit PC1 may be disposed on the substrate 100, and the first light-emitting diode ED1 may be disposed on the first sub-pixel circuit PC1, at (e.g., in or on) the first display area DA1. The substrate 100 may include a glass material or a polymer resin.

A buffer layer 201 may be disposed on the upper surface of the substrate 100. The buffer layer 201 may prevent or substantially prevent impurities from penetrating a semiconductor layer of a transistor. The buffer layer 201 may include one or more suitable inorganic insulating materials, such as silicon nitride, silicon oxynitride, and/or silicon oxide, and may be a single layer or multi-layers including one or more of the inorganic insulating materials.

The first sub-pixel circuit PC1 may be disposed on the buffer layer 201. As described above with reference to FIG. 4, the first sub-pixel circuit PC1 may include a plurality of thin-film transistors, and a storage capacitor. FIG. 6B shows the first transistor T1, the third transistor T3, the sixth transistor T6, and the storage capacitor Cst.

The first transistor T1 may include a first semiconductor layer A1 disposed on the buffer layer 201, and a first gate electrode GE1 overlapping with a channel area C1 of the first semiconductor layer A1. The first semiconductor layer A1 may include a silicon semiconductor material (e.g., polysilicon). The first semiconductor layer A1 may include the channel area C1, and a first area B1 and a second area D1 arranged on opposite sides of the channel area C1. The first area B1 and the second area D1 are areas containing impurities with higher concentrations than that in the channel area C1. Any one of the first area B1 and the second area D1 may be a source area, and the other thereof may be a drain area.

The sixth transistor T6 may include a sixth semiconductor layer A6 disposed on the buffer layer 201, and a sixth gate electrode GE6 overlapping with a channel area C6 of the sixth semiconductor layer A6. The sixth semiconductor layer A6 may include a silicon semiconductor material (e.g., polysilicon). The sixth semiconductor layer A6 may include the channel area C6, and a first area B6 and a second area D6 arranged on opposite sides of the channel area C6. The first area B6 and the second area D6 are areas containing impurities with higher concentrations than that in the channel area C6. Any one of the first area B6 and the second area D6 may be a source area, and the other thereof may be a drain area.

The first gate electrode GE1 and the sixth gate electrode GE6 may each include a conductive material including molybdenum (Mo), aluminum (Al), copper (Cu), titanium (Ti), or the like, and may have a single-layer structure or a multilayered structure including one or more of the above materials. A first gate insulating layer 203 may be disposed under the first gate electrode GE1 and the sixth gate electrode GE6 to electrically insulate the same from the first semiconductor layer A1 and the sixth semiconductor layer A6. The first gate insulating layer 203 may include one or more inorganic insulating materials, such as silicon nitride, silicon oxynitride, and/or silicon oxide, and may be a single layer or multi-layers including one or more of the inorganic insulating materials.

The storage capacitor Cst may include the lower electrode CE1 and the upper electrode CE2, which overlap with each other. In an embodiment, the lower electrode CE1 of the storage capacitor Cst may include the first gate electrode GE1. In other words, the first gate electrode GE1 may include the lower electrode CE1 of the storage capacitor Cst. For example, the first gate electrode GE1 may be integrally formed with the lower electrode CE1 of the storage capacitor Cst.

A first interlayer insulating layer 205 may be arranged between the lower electrode CE1 and the upper electrode CE2 of the storage capacitor Cst. The first interlayer insulating layer 205 may include one or more inorganic insulating materials, such as silicon nitride, silicon oxynitride, and/or silicon oxide, and may be a single-layer structure or a multilayered structure including one or more of the inorganic insulating materials.

The upper electrode CE2 of the storage capacitor Cst may include one or more low-resistance conductive materials, such as Mo, Al, Cu, and/or Ti, and may be a single-layer structure or a multilayered structure including one or more of the above materials.

A second interlayer insulating layer 207 may be disposed on the storage capacitor Cst. The second interlayer insulating layer 207 may include one or more inorganic insulating materials, such as silicon nitride, silicon oxynitride, and/or silicon oxide, and may be a single-layer structure or a multilayered structure including one or more of the inorganic insulating materials.

A third semiconductor layer A3 of the third transistor T3 may be disposed on the second interlayer insulating layer 207. The third semiconductor layer A3 may include an oxide semiconductor material. For example, the third semiconductor layer A3 may include a Zn oxide-based material, for example, such as Zn oxide, In—Zn oxide, Ga—In—Zn oxide, or the like. In some embodiments, the third semiconductor layer A3 may be an In—Ga—Zn—O (IGZO) semiconductor, an In—Sn—Zn—O (ITZO) semiconductor, or an In—Ga—Sn—Zn—O (IGTZO) semiconductor, in which a suitable metal, such as indium (In), gallium (Ga), or tin (Sn), is included in ZnO.

The third semiconductor layer A3 may include a channel area C3, and a first area B3 and a second area D3 arranged on opposite sides of the channel area C3. Any one of the first area B3 and the second area D3 may be a source area, and the other thereof may be a drain area.

The third transistor T3 may include a third gate electrode GE3 overlapping with the channel area C3 of the third semiconductor layer A3. The third gate electrode GE3 may have a double gate structure including a lower gate electrode G3A disposed under the third semiconductor layer A3, and an upper gate electrode G3B disposed above the channel area C3.

The lower gate electrode G3A may be disposed at (e.g., in or on) the same layer (e.g., on the first interlayer insulating layer 205) as that of the upper electrode CE2 of the storage capacitor Cst. The lower gate electrode G3A may include the same material as that of the upper electrode CE2 of the storage capacitor Cst.

The upper gate electrode G3B may be disposed above the third semiconductor layer A3, with a second gate insulating layer 209 therebetween. The second gate insulating layer 209 may include one or more inorganic insulating materials, such as silicon nitride, silicon oxynitride, and/or silicon oxide, and may be a single-layer structure or a multilayered structure including one or more of the inorganic insulating materials.

A third interlayer insulating layer 210 may be disposed on the upper gate electrode G3B. The third interlayer insulating layer 210 may include an inorganic insulating material, such as silicon oxynitride, and may be a single-layer structure or a multilayered structure including the inorganic insulating material.

FIG. 6B shows that the upper electrode CE2 of the storage capacitor Cst is disposed at (e.g., in or on) the same layer as that of the lower gate electrode G3A of the third gate electrode GE3, but the present disclosure is not limited thereto. In another embodiment, the upper electrode CE2 of the storage capacitor Cst may be arranged at (e.g., in or on) the same layer as that of the third semiconductor layer A3, and may include the same material as that of the first area B3 and the second area D3 of the third semiconductor layer A3.

The first transistor T1 may be electrically connected to the third transistor T3 through the node connection line 166. The node connection line 166 may be disposed on the third interlayer insulating layer 210. One side of the node connection line 166 may contact the first gate electrode GE1 of the first transistor T1, and another side of the node connection line 166 may contact the first area B3 of the third semiconductor layer A3 of the third transistor T3.

The node connection line 166 may include Al, Cu, and/or Ti, and may be a single layer or multi-layers including one or more of the above materials. For example, the node connection line 166 may have a three-layered structure of a Ti layer, an Al layer, and a Ti layer.

A first organic insulating layer 211 may be disposed on the node connection line 166. The first organic insulating layer 211 may include an organic insulating material. The organic insulating material may include acryl, benzocyclobutene (BCB), polyimide, hexamethyldisiloxane (HMDSO), or the like.

The data line DL and the driving power line PL may be disposed on the first organic insulating layer 211. The data line DL and the driving power line PL may each include Al, Cu, and/or Ti, and may each be a single layer or multi-layers including one or more of the above materials. For example, the data line DL and the driving power line PL may have a three-layered structure of a Ti layer/an Al layer/a Ti layer.

FIG. 6B shows that the data line DL and the driving power line PL are disposed at (e.g., in or on) the same layer (e.g., on the first organic insulating layer 211) as each other, but in another embodiment, the data line DL and the driving power line PL may be disposed at (e.g., in or on) different layers from each other.

A second organic insulating layer 213 may be disposed on the first organic insulating layer 211. The second organic insulating layer 213 may include an organic insulating material, such as acryl, BCB, polyimide, or HMDSO.

A first electrode 221 of the first light-emitting diode ED1 may be disposed on the second organic insulating layer 213. The first electrode 221 may be electrically connected to the sixth transistor T6 through a first contact metal CM1 and a second contact metal CM2. The first contact metal CM1 may be formed at (e.g., in or on) the same layer as and include the same material as those of the node connection line 166. The second contact metal CM2 may be formed at (e.g., in or on) the same layer as and include the same material as those of the data line DL and/or the driving power line PL.

The first electrode 221 of the first light-emitting diode ED1 may include a reflection layer including silver (Ag), magnesium (Mg), Al, platinum (Pt), palladium (Pd), gold (Au), nickel (Ni), neodymium (Nd), iridium (Ir), chromium (Cr), or a suitable compound thereof. In another embodiment, the first electrode 221 may further include a conductive oxide layer on and/or under the reflection layer. The conductive oxide layer may include indium tin oxide (ITO), indium zinc oxide (IZO), zinc oxide (ZnO), indium oxide (In₂O₃), indium gallium oxide (IGO), and/or aluminum zinc oxide (AZO). In an embodiment, the first electrode 221 may include a plurality of sub-layers. For example, the first electrode 221 may include a first sub-layer, a second sub-layer, and a third sub-layer. The first sub-layer to the third sub-layer may be an ITO layer, an Ag layer, and an ITO layer, respectively.

A bank layer 215 may be disposed on the first electrode 221. The bank layer 215 may include an opening 2150P overlapping with the first electrode 221, and may cover edges thereof. The bank layer 215 may include an organic insulating material, such as polyimide.

A spacer 217 may be formed on the bank layer 215. The spacer 217 and the bank layer 215 may be formed together through the same or substantially the same process, or may be independently formed from each other through separate processes. In an embodiment, the spacer 217 may include an organic insulating material, such as polyimide. In another embodiment, the bank layer 215 may include an organic insulating material including a light-shielding dye, and the spacer 217 may include an organic insulating material, such as polyimide.

An intermediate layer 222 includes an emission layer 222b. The intermediate layer 222 may include a first functional layer 222a disposed under the emission layer 222b, and/or a second functional layer 222c disposed above the emission layer 222b. The emission layer 222b may include a high-molecular-weight or low-molecular-weight organic material for emitting a suitable color (e.g., a certain or predetermined color) of light (e.g., red, green, or blue light). In another embodiment, the emission layer 222b may include an inorganic material or quantum dots.

The first functional layer 222a may include a Hole Transport Layer (HTL) and/or a Hole Injection Layer (HIL). The second functional layer 222c may include an Electron Transport Layer (ETL) and/or an Electron Injection Layer (EIL). The first functional layer 222a and the second functional layer 222c may include organic materials.

The emission layer 222b may be formed at (e.g., in or on) the first display area DA1 to overlap with the first electrode 221 through the opening 2150P in the bank layer 215. On the other hand, an organic material layer included in the intermediate layer 222 (e.g., the first functional layer 222a and/or the second functional layer 222c) may entirely cover the display area DA (e.g., see FIG. 3).

The intermediate layer 222 may have a single-stack structure including an emission layer, or a tandem structure that is a multi-stacked structure including emission layers. When the intermediate layer 222 has a tandem structure, a charge generation layer (CGL) may be arranged between stacks.

A second electrode 223 may include a conductive material having a low work function. For example, the second electrode 223 may include a transparent (or translucent) layer including Ag, Mg, Al, Pt, Pd, Au, Ni, Nd, Ir, Cr, Li, Ca, or a suitable alloy thereof. As another example, the second electrode 223 may further include a layer including ITO, IZO, ZnO, or In₂O₃ on the transparent (or translucent) layer including one or more of the above materials. The second electrode 223 may entirely cover the display area DA (e.g., see FIG. 3).

A capping layer 225 may be disposed on the second electrode 223. The capping layer 225 may include an inorganic material or an organic material. The capping layer 225 may include LiF, an inorganic insulating material, and/or an organic insulating material. The capping layer 225 may entirely cover the display area DA.

The first light-emitting diode ED1 may be covered by the encapsulation layer 300. The encapsulation layer 300 may include at least one inorganic encapsulation layer, and at least one organic encapsulation layer. In an embodiment, FIG. 6B shows that the encapsulation layer 300 includes a first inorganic encapsulation layer 310 and a second inorganic encapsulation layer 330, and an organic encapsulation layer 320 therebetween. The encapsulation layer 300 may be disposed on the capping layer 225.

The first inorganic encapsulation layer 310 and the second inorganic encapsulation layer 330 may each include one or more inorganic materials selected from among aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may each be a single layer or multi-layers including one or more of the above materials. The organic encapsulation layer 320 may include a polymer-based material. The polymer-based material may include acrylic resin, epoxy-based resin, polyimide, polyethylene, and/or the like. In an embodiment, the organic encapsulation layer 320 may include acrylate.

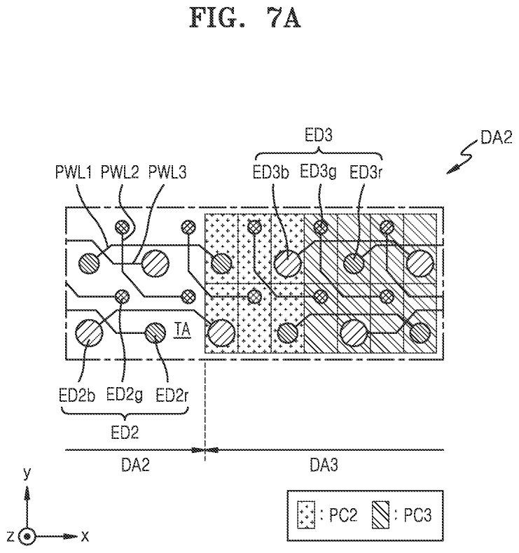

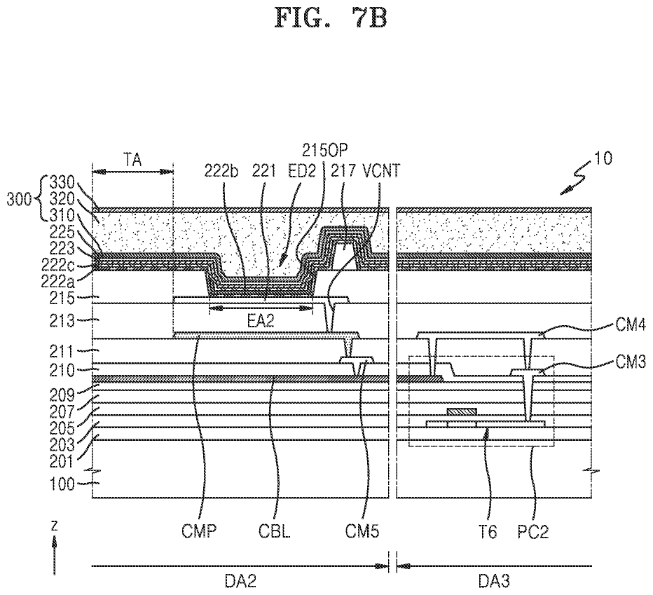

FIG. 7A is a plan view of a second display area and a third display area of a display panel, according to an embodiment. FIG. 7B is a cross-sectional view of the second display area and the third display area of the display panel, according to an embodiment.

Referring to FIG. 7A, light-emitting diodes (e.g., the second light-emitting diodes ED2 and the third light-emitting diodes ED3) may be arranged at (e.g., in or on) the second display area DA2 and the third display area DA3. The sub-pixel circuits electrically connected to the second light-emitting diodes ED2 and the third light-emitting diodes ED3 at (e.g., in or on) the second display area DA2 and the third display area DA3 may be arranged at (e.g., in or on) the third display area DA3. In other words, the sub-pixel circuits are not arranged at (e.g., in or on) the second display area DA2, and thus, the area of the transmission area TA may increase.

The second light-emitting diodes ED2 may include a 2-1 light-emitting diode, a 2-2 light-emitting diode, and a 2-3 light-emitting diode, which emit different colors of light from each other. The third light-emitting diodes ED3 may include a 3-1 light-emitting diode, a 3-2 light-emitting diode, and a 3-3 light-emitting diode, which emit different colors of light from each other. Hereinafter, the 2-1 light-emitting diode, the 2-2 light-emitting diode, and the 2-3 light-emitting diode are referred to as a second red light-emitting diode ED2r, a second green light-emitting diode ED2g, and a second blue light-emitting diode ED2b, respectively. The 3-1 light-emitting diode, the 3-2 light-emitting diode, and the 3-3 light-emitting diode are referred to as a third red light-emitting diode ED3r, a third green light-emitting diode ED3g, and a third blue light-emitting diode ED3b, respectively.

In other words, the second light-emitting diodes DE2 may include the second red light-emitting diodes ED2r, the second green light-emitting diodes ED2g, and the second blue light-emitting diodes ED2b. The third light-emitting diodes ED3 may include third red light-emitting diodes ED3r, third green light-emitting diodes ED3g, and third blue light-emitting diodes ED3b.

The arrangements of the second light-emitting diodes ED2 and the third light-emitting diodes ED3 may be the same or substantially the same as the arrangements of the red sub-pixels, the green sub-pixels, and the blue sub-pixels described above with reference to FIG. 5. For example, the second red light-emitting diode ED2r, the second green light-emitting diode ED2g, and the second blue light-emitting diode ED2b may have a diamond type arrangement (e.g., a PENTILE® arrangement). Similarly, the third red light-emitting diode ED3r, the third green light-emitting diode ED3g, and the third blue light-emitting diode ED3b may have a may have a diamond type arrangement (e.g., a PENTILE® arrangement).

Some light-emitting diodes, which emit the same color of light from each other, from among the second light-emitting diodes ED2 and the third light-emitting diodes ED3 may be electrically connected to each other through a connection line. The first light-emitting diodes ED1 at (e.g., in or on) the first display area DA1 shown in FIG. 6A may be electrically connected to the first sub-pixel circuits PC1 at (e.g., in or on) the first display area DA1. For example, one first light-emitting diode ED1 may correspond to one first sub-pixel circuit PC1 (e.g., in a one-to-one correspondence).

On the other hand, one second sub-pixel circuit PC2 may be electrically connected to two second light-emitting diodes ED2 that emit the same color of light as each other (e.g., in a one-to-two correspondence). For example, any one of the second sub-pixel circuits PC2 may be electrically connected to two second red light-emitting diodes ED2r that are connected to each other by a first connection line PWL1 that is a conductive line. Similarly, another one of the second sub-pixel circuits PC2 may be electrically connected to two second green light-emitting diodes ED2g that are connected to each other by a second connection line PWL2. Another one of the second sub-pixel circuits PC2 may be electrically connected to two second blue light-emitting diodes ED2b that are connected to each other by a third connection line PWL3.

One third sub-pixel circuit PC3 may be electrically connected to two third light-emitting diodes ED3 that emit the same color of light as each other (e.g., in a one-to-two correspondence). For example, any one of the third sub-pixel circuits PC3 may be electrically connected to a plurality of third red light-emitting diodes ED3r (e.g., two third red light-emitting diodes ED3r) that are connected to each other by the first connection line PWL1. Similarly, another of the third sub-pixel circuits PC3 may be electrically connected to two third green light-emitting diodes ED3g that are connected to each other by the second connection line PWL2. Another one of the third sub-pixel circuits PC3 may be electrically connected to two third blue light-emitting diodes ED3b that are connected to each other by the third connection line PWL3.

Because the transmission area TA is located at (e.g., in or on) the second display area DA2, the second light-emitting diodes ED2 and the second sub-pixel circuits PC2, which are arranged at (e.g., in or on) different areas from each other, may be electrically connected to each other by the conductive bus line CBL, as shown in FIG. 7B.

Referring to FIG. 7B, the second sub-pixel circuit PC2 disposed on the substrate 100 may be located at (e.g., in or on) the third display area DA3, and the second light-emitting diode ED2 electrically connected to the second sub-pixel circuit PC2 may be arranged at (e.g., in or on) the second display area DA2. As described above with reference to FIG. 4, the second sub-pixel circuit PC2 may include a plurality of thin-film transistors, and a storage capacitor. In this regard, FIG. 7B shows the sixth transistor T6 of the second sub-pixel circuit PC2.

The buffer layer 201, the first gate insulating layer 203, the first interlayer insulating layer 205, the second interlayer insulating layer 207, the second gate insulating layer 209, the third interlayer insulating layer 210, the first organic insulating layer 211, and the second organic insulating layer 213 may be disposed above the substrate 100.

The second sub-pixel circuit PC2 may be electrically connected to the second light-emitting diode ED2 through the conductive bus line CBL extending from the third display area DA3 towards the second display area DA2.

The conductive bus line CBL may include a metal material. For example, the conductive bus line CBL may be disposed at (e.g., in or on) the same layer as and may include the same material as those of a gate electrode of a first transistor, electrodes of a storage capacitor, or a gate electrode of a third transistor. In some embodiments, the conductive bus line CBL may include a conductive material containing a metal, such as Mo, Al, Cu, Ti, or the like, through which light does not penetrate, and may have a single-layer structure or a multilayered structure including one or more of the above materials. In an embodiment, FIG. 7B shows that the conductive bus line CBL is disposed on the second gate insulating layer 209, but in another embodiment, the conductive bus line CBL may be disposed above the first gate insulating layer 203 or the first interlayer insulating layer 205. In another embodiment, the conductive bus line CBL may include a transparent conductive oxide (TCO).

The conductive bus line CBL may electrically connect the second sub-pixel circuit PC2 to the second light-emitting diode ED2 through a third contact metal CM3 to a fifth contact metal CM5. The third contact metal CM3 may be disposed on the third interlayer insulating layer 210. The fourth contact metal CM4 may be disposed on the first organic insulating layer 211, and may electrically connect the third contact metal CM3 to the conductive bus line CBL at (e.g., in or on) the third display area DA3.

The conductive bus line CBL may extend towards the second display area DA2 from the third display area DA3. The fifth contact metal CM5 may be disposed above the conductive bus line CBL, with the third interlayer insulating layer 210 therebetween, and may contact a portion of the conductive bus line CBL through a contact hole penetrating the third interlayer insulating layer 210. The first electrode 221 of the second light-emitting diode ED2 may be electrically connected to the fifth contact metal CM5. For example, the first electrode 221 of the second light-emitting diode ED2 may be electrically connected to the fifth contact metal CM5 via a conductive pattern layer CMP arranged between the first electrode 221 of the second light-emitting diode ED2 and the fifth contact metal CM5.

The conductive pattern layer CMP may be disposed above the conductive bus line CBL, and under the first electrode 221 of the second light-emitting diode ED2. For example, the conductive pattern layer CMP may be arranged between the first organic insulating layer 211 and the second organic insulating layer 213.

The conductive pattern layer CMP may overlap with the first electrode 221 of the second light-emitting diode ED2. The conductive pattern layer CMP may overlap with an emission area EA2 of the second light-emitting diode ED2. The emission area EA2 of the second light-emitting diode ED2 may be defined by an opening 2150P in the bank layer 215, which overlaps with the first electrode 221 of the second light-emitting diode ED2. Therefore, when the conductive pattern layer CMP is described as overlapping with the emission area EA2 of the second light-emitting diode ED2, the conductive pattern layer CMP overlaps with the opening 2150P of the bank layer 215, which corresponds to the emission area EA2 of the second light-emitting diode ED2. The conductive pattern layer CMP may include a suitable area (e.g., a certain or predetermined area) and/or a suitable pattern (e.g., a certain or predetermined pattern) to overlap with the first electrode 221 of the second light-emitting diode ED2 and/or the opening 2150P in the bank layer 215 that corresponds to the emission area EA2 of the second light-emitting diode ED2.

As described above with reference to FIG. 6B, the first sub-pixel circuit PC1 and at least one line (e.g., WL of FIG. 6B) connected thereto may be disposed under the first electrode 221 of the first light-emitting diode ED1 at (e.g., in or on) the first display area DA1. The line (e.g., WL of FIG. 6B) may have an area and/or a pattern overlapping with the entire emission area (e.g., EA1 of FIG. 6B) of the first light-emitting diode ED1, or overlapping with only a portion of the emission area (e.g., EA1 of FIG. 6B) of the first light-emitting diode ED1. Because the emission area (e.g., EA1 of FIG. 6B) of the first light-emitting diode ED1 is defined by the opening 2150P of the bank layer 215 disposed above the first electrode 221 of the first light-emitting diode ED1, the emission area EA1 of the first light-emitting diode ED1 may indicate the opening 2150P of the bank layer 215 that is on the first electrode 221 of the first light-emitting diode ED1.

Although the second organic insulating layer 213 is arranged for the planarization, a vertical distance between the upper surface of the substrate 100 and a lower surface of the first electrode 221 of the first light-emitting diode ED1 may not be uniform, because of electrodes and/or lines of the first sub-pixel circuit (e.g., PC1 of FIG. 6B) disposed under the second organic insulating layer 213. Unlike in the first display area DA1, in the second display area DA2, no sub-pixel circuits are disposed under the first electrode 221 of the second light-emitting diode ED2, and thus, the number of lines passing the second display area DA2 is smaller because there are no sub-pixel circuits. Therefore, a vertical distance from the upper surface of the substrate 100 to a lower surface of the first electrode 221 of the second light-emitting diode ED2 may be different from the vertical distance from the upper surface of the substrate 100 to the lower surface of the first electrode 221 of the first light-emitting diode ED1. In other words, a gradient of the first electrode 221 of the first light-emitting diode ED1 at (e.g., in or on) the first display area DA1 (e.g., a gradient of the first electrode 221 of the first light-emitting diode ED1 with respect to a virtual plane parallel to or substantially parallel to the upper surface of the substrate 100) may be different from a gradient of the first electrode 221 of the second light-emitting diode ED2 at (e.g., in or on) the second display area DA2 (e.g., a gradient of the first electrode 221 of the second light-emitting diode ED2 with respect to the virtual plane parallel to or substantially parallel to the upper surface of the substrate 100). In this case, although the first light-emitting diode ED1 and the second light-emitting diode ED2 emit the same color of light as each other, the light emitted from the first light-emitting diode ED1 and the light emitted from the second light-emitting diode ED2 may be differently recognized by a user. In this case, the user may recognize that the second display area DA2 is different from the first display area DA1, and as a result, the second display area DA2 and the first display area DA1 are differently viewed by the user.

However, according to an embodiment, as shown in FIG. 7B, as the conductive pattern layer CMP is disposed under the first electrode 221 of the second light-emitting diode ED2 to overlap with the same, the aforementioned issues may be prevented or reduced. The conductive pattern layer CMP may overlap with the emission area EA2 of the second light-emitting diode ED2 and the opening 2150P of the bank layer 215. At least a portion of the conductive pattern layer CMP may have a shape that is the same or substantially the same as (or similar to) a shape of a portion in which the first electrode 221 of the first light-emitting diode ED1 overlaps with the line WL under the first electrode 221.

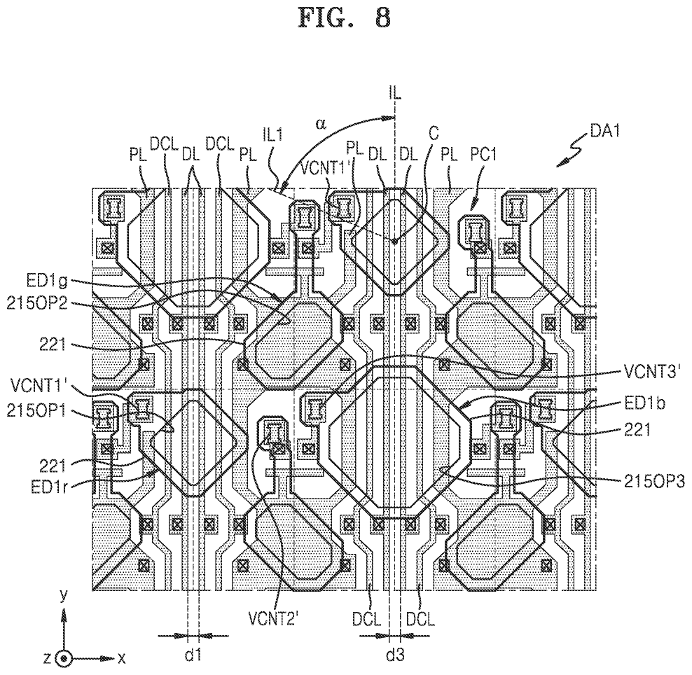

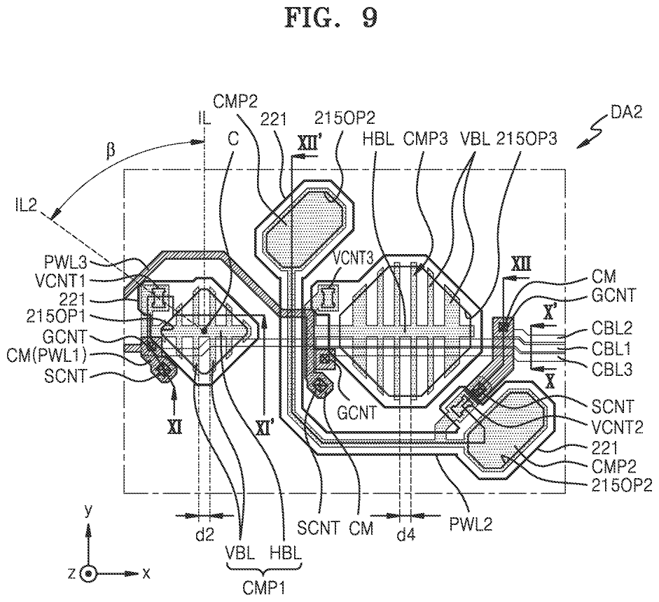

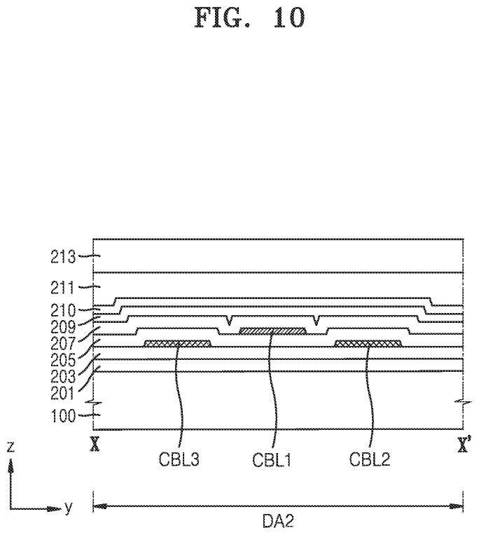

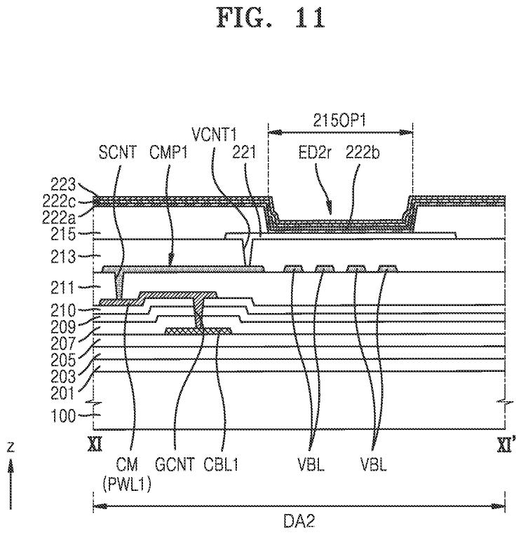

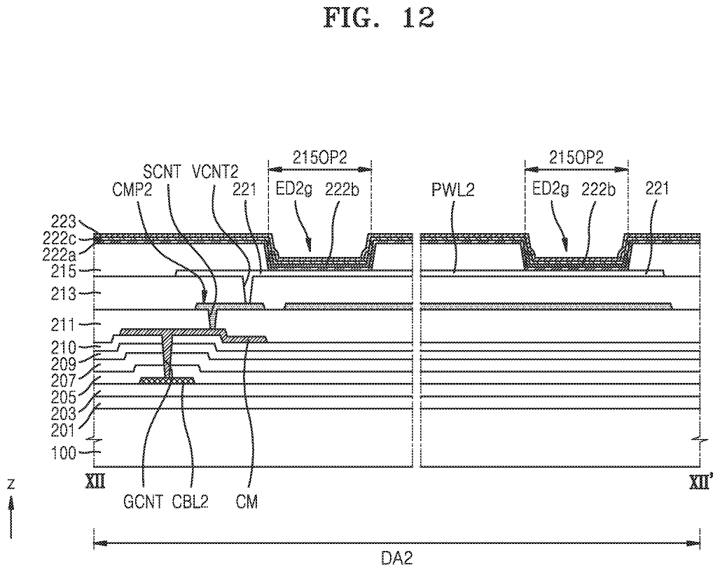

FIG. 8 is a plan view of a portion of a first display area of a display panel, according to an embodiment. FIG. 9 is a plan view of a portion of a second display area of the display panel, according to an embodiment. FIG. 10 is a cross-sectional view of the display panel taken along the line X-X′ of FIG. 9, according to an embodiment. FIG. 11 is a cross-sectional view of the display panel taken along the line XI-XI′ of FIG. 9, according to an embodiment. FIG. 12 is a cross-sectional view of the display panel taken along the line XII-XII′ of FIG. 9, according to an embodiment.

FIG. 8 shows first light-emitting diodes arranged at (e.g., in or on) the first display area DA1 (e.g., the first red light-emitting diodes ED1r, the first green light-emitting diodes ED1g, and the first blue light-emitting diodes ED1b). At least one line (e.g., at least one signal line) may be disposed under the first electrode 221 of each of the first red light-emitting diode ED1r, the first green light-emitting diode ED1g, and the first blue light-emitting diode ED1b. At least one line or at least one signal line may include a data line DL, the data connection line DCL, and/or the driving power line PL arranged between the first organic insulating layer 211 (e.g., see FIG. 7B) and the second organic insulating layer 213 (e.g., see FIG. 7B).

The data line DL, the data connection line DCL, and the driving power line PL may extend in the second direction (e.g., the y direction). In an embodiment, FIG. 8 shows that the data line DL, the data connection line DCL, and the driving power line PL pass areas where the first sub-pixel circuits PC1 are arranged, and lines passing two adjacent first sub-pixel circuits PC1 are horizontally symmetrical to each other with respect to a virtual line in the second direction (e.g., the y direction). The areas indicated by dashed lines in FIG. 8 are the areas where the first sub-pixel circuits PC1 are arranged, and the first sub-pixel circuits PC1 may be arranged along the first direction (e.g., the x direction, a row direction) and the second direction (e.g., the y direction, a column direction) to form rows and columns.

The data line DL passing the first sub-pixel circuit PC1 may be electrically connected to a corresponding one of the first sub-pixel circuits PC1, and the data connection line DCL passing the first sub-pixel circuit PC1 may be electrically connected to the first sub-pixel circuit PC1 arranged in another column. For example, the data line DL passing a first sub-pixel circuit PC1 arranged in a j^{th} column may be electrically connected to the first sub-pixel circuit PC1 arranged in the j^{th} column, and the data connection line DCL passing the first sub-pixel circuit PC1 arranged in the j^{th} column may be electrically connected to a first sub-pixel circuit PC1 arranged in a (j−k)^{th} column (where j is a natural number and k is a natural number less than j).

The first electrode 221 of the first red light-emitting diode ED1r may overlap with a portion of each of two data lines DL, a portion of each of two data connection lines DCL, and a portion of each of two driving power lines PL. The first electrode 221 of the first blue light-emitting diode ED1b may overlap with a portion of each of two data lines DL, a portion of each of two data connection lines DCL, and a portion of each of two driving power lines PL. The first electrode 221 of the first green light-emitting diode ED1g may overlap with two driving power lines PL. In an embodiment, as shown in FIG. 8, a portion of each of two adjacent driving power lines PL may be physically connected to each other. Such physical connection may indicate that the driving power lines PL are integrally formed with each other. The first electrode 221 of the first green light-emitting diode ED1g may overlap with a connection portion of the driving power lines PL (e.g., a portion in which the driving power lines PL are integrally connected to each other).

The emission area of the first light-emitting diode may overlap with at least one line disposed under the first electrode 221 (e.g., two data lines DL, two data connection lines DCL, and/or two driving power lines PL). In other words, the opening of the bank layer that overlaps with the first electrode 221 of the first light-emitting diode may overlap with a portion of each of two data lines DL, a portion of each of two data connection lines DCL, and/or a portion of each of two driving power lines PL.

The emission area of the first red light-emitting diode ED1r (e.g., an opening 215OP1 of the bank layer that overlaps with the first electrode 221 of the first red light-emitting diode ED1r) may overlap with a portion of two data lines DL that are spaced apart from each other in the first direction (e.g., the x direction), a portion of each of two data connection lines DCL, and a portion of two driving power lines PL.

The emission area of the first green light-emitting diode ED1g (e.g., an opening 215OP2 of the bank layer that overlaps with the first electrode 221 of the first green light-emitting diode ED1g) may overlap with a connection portion of two driving power lines PL. The opening 215OP2 of the bank layer that corresponds to the emission area of the first green light-emitting diode ED1g may have a smaller area than an area of the connection portion of two driving power lines PL, and the entire opening 215OP2 of the bank layer that corresponds to the emission area of the first green light-emitting diode ED1g may overlap with the connection portion of two driving power lines PL.

The emission area of the first blue light-emitting diode ED1b (e.g., an opening 215OP3 of the bank layer that overlaps with the first electrode 221 of the first blue light-emitting diode ED1b) may overlap with a portion of two data lines DL that are spaced apart from each other in the first direction (e.g., the x direction), a portion of each of two data connection lines DCL, and a portion of two driving power lines PL.

FIG. 9 shows second light-emitting diodes at (e.g., in or on) the second display area DA2 (e.g., the second red light-emitting diodes ED2r, the second green light-emitting diodes ED2g, and the second blue light-emitting diodes ED2b). The first electrode 221 of each second light-emitting diode overlaps with a conductive pattern layer. For example, the first electrodes 221 of the second red light-emitting diode ED2r, the second green light-emitting diode ED2g, and the second blue light-emitting diode ED2b overlap with a first conductive pattern layer CMP1, a second conductive pattern layer CMP2, and a third conductive pattern layer CMP3, respectively.

The first conductive pattern layer CMP1 to the third conductive pattern layer CMP3 may be disposed at (e.g., in or on) the same layer (e.g., on the first organic insulating layer) as each other, and may include the same material as that of the data lines DL, the data connection lines DCL, and the driving power lines PL, which are described above with reference to FIG. 8. As described above with reference to FIG. 7B, the first conductive pattern layer CMP1 to the third conductive pattern layer CMP3 may be arranged between the first organic insulating layer 211 and the second organic insulating layer 213. The first conductive pattern layer CMP1 to the third conductive pattern layer CMP3 may each have a stacked structure including a Ti layer, an Al layer, and a Ti layer.

The first conductive pattern layer CMP1 may overlap with the first electrode 221 of the second red light-emitting diode ED2r, and the opening 215OP1 of the bank layer disposed on the first electrode 221 of the second red light-emitting diode ED2r.

The first conductive pattern layer CMP1 may include conductive lines VBL overlapping with the first electrode 221 of the second red light-emitting diode ED2r and/or the opening 215OP1 of the bank layer. The conductive lines VBL may extend in the second direction (e.g., the y direction). The conductive lines VBL may be arranged to be spaced apart from each other in the first direction (e.g., the x direction).

The conductive lines VBL that are spaced apart from each other may be electrically and physically connected to each other by a connection conductive line HBL. The connection conductive line HBL may extend to cross the conductive lines VBL. In an embodiment, FIG. 9 shows that the connection conductive line HBL extends in the first direction (e.g., the x direction). In an embodiment, the connection conductive line HBL may pass the first electrode 221 or a center C of the opening 215OP1 of the bank layer. The physical connection indicates an integral connection, and the connection conductive line HBL may be integrally connected to the conductive lines VBL.

At least some of the conductive lines VBL of the first conductive pattern layer CMP1 may overlap with the emission area of the second red light-emitting diode ED2r (e.g., the opening 215OP1 of the bank layer). Locations and/or the number of conductive lines VBL overlapping with the emission area of the second red light-emitting diode ED2r (e.g., the opening 215OP1 of the bank layer) may be the same as locations and/or the number of lines overlapping with the opening 215OP1 of the bank layer that corresponds to the emission area of the first red light-emitting diode ED1r.

From among the lines overlapping with the emission area of the first red light-emitting diode ED1r, a first distance d1 (e.g., see FIG. 8) between an n^{th} line and an (n+1)^{th} line may be the same or substantially the same as a second distance d2 (e.g., see FIG. 9) between an n^{th} conductive line and an (n+1)^{th} conductive line from among the conductive lines VBL overlapping with the emission area of the second red light-emitting diode ED2r (where n is a natural number). Here, relative locations of the n^{th} line and the (n+1)^{th} line with respect to the emission area of the first red light-emitting diode ED1r may be the same or substantially the same as relative locations of the n^{th} conductive line and the (n+1)^{th} conductive line with respect to the emission area of the second red light-emitting diode ED2r. In other words, a width of each conductive line VBL overlapping with the opening 215OP1 of the bank layer that corresponds to the emission area of the second red light-emitting diode ED2r, a distance between the conductive lines VBL, and/or a location of each conductive line VBL may be the same or substantially the same as a width of each line overlapping with the opening 215OP1 of the bank layer that corresponds to the emission area of the first red light-emitting diode ED1r, a distance between the lines, and/or a location of each line.

Similarly, the third conductive pattern layer CMP3 may include the conductive lines VBL overlapping with the first electrode 221 of the second blue light-emitting diode ED2b, and the opening 215OP3 of the bank layer. The conductive lines VBL may be spaced apart from each other in the first direction (e.g., the x direction), and may extend in the second direction (e.g., the y direction). The conductive lines VBL may be electrically and physically (e.g., integrally) connected to each other by the connection conductive lines HBL crossing the conductive lines VBL and extending in the first direction (e.g., the x direction).

The locations and/or the number of conductive lines VBL of the third conductive pattern layer CMP3 which overlap with the first electrode 221 of the second blue light-emitting diode ED2b and the opening 215OP3 of the bank layer may be the same or substantially the same as the locations and/or the number of lines which overlap with the first electrode 221 of the first blue light-emitting diode ED1b and the opening 215OP3 of the bank layer described above with reference to FIG. 8.

From among the lines overlapping with the emission area of the first blue light-emitting diode ED1b, a third distance d3 (e.g., see FIG. 8) between an m^{th} line and an (m+1)^{th} line may be the same or substantially the same as a fourth distance d4 (e.g., see FIG. 9) between an m^{th} conductive line and an (m+1)^{th} conductive line from among the conductive lines VBL overlapping with the emission area of the second blue light-emitting diode ED2b. Here, relative locations of the m^{th} line and the (m+1)^{th} line with respect to the emission area of the first blue light-emitting diode ED1b may be the same or substantially the same as relative locations of the m^{th} conductive line and the (m+1)^{th} conductive line with respect to the emission area of the second blue light-emitting diode ED2b (where m is a natural number). In other words, a width of each conductive line VBL overlapping with the opening 215OP3 of the bank layer that corresponds to the emission area of the second blue light-emitting diode ED2b, the distance between the conductive lines VBL, and/or the location of each conductive line VBL may be the same or substantially the same as a width of each line overlapping with the opening 215OP3 of the bank layer that corresponds to the emission area of the first blue light-emitting diode ED1b, the distance between the lines, and/or the location of each line.

The second conductive pattern layer CMP2 may overlap with the first electrode 221 of the second green light-emitting diode ED2g, and the opening 215OP2 of the bank layer disposed on the first electrode 221 of the second green light-emitting diode ED2g.

In the plane (e.g., in a plan view), a shape and/or an area in which the opening 215OP2 of the bank layer that corresponds to the emission area of the second green light-emitting diode ED2g overlaps with the second conductive pattern layer CMP2 may be the same or substantially the same as a shape and/or an area in which the opening 215OP2 of the bank layer that corresponds to the emission area of the first green light-emitting diode ED1g overlaps with at least one line (e.g., a connection portion of two driving power lines PL).

In an embodiment, the second conductive pattern layer CMP2 may have a shape and/or an area that may overlap with the entire emission area of the second green light-emitting diode ED2g. In an embodiment, as shown in FIG. 8, when the entire opening 215OP2 of the bank layer corresponding to the entire emission area of the first green light-emitting diode ED1g overlaps with the connection portion of two driving power lines PL, the second conductive pattern layer CMP2 may have a shape and/or an area that entirely overlaps with the opening 215OP2 of the bank layer corresponding to the entire emission area of the second green light-emitting diode ED2g, as shown in FIG. 9.

As described above with reference to FIG. 7B, each second light-emitting diode may be connected to the second sub-pixel circuit through the conductive bus line. FIG. 9 shows a first conductive bus line CBL1, a second conductive bus line CBL2, and a third conductive bus line CBL3 that are electrically connected to the second red light-emitting diode ED2r, the second green light-emitting diode ED2g, and the second blue light-emitting diode ED2b, respectively.

At least one selected from among the first conductive bus line CBL1, the second conductive bus line CBL2, and the third conductive bus line CBL3 may be disposed at (e.g., in or on) a different layer from that of another one thereof. For example, the first conductive bus line CBL1, the second conductive bus line CBL2, and the third conductive bus line CBL3 may be arranged at (e.g., in or on) the same layer as each other, and may include the same material as that of at least one of a first gate electrode of a first transistor of a sub-pixel circuit, electrodes of a storage capacitor, and/or a third gate electrode of a third transistor.

In an embodiment, FIG. 10 shows that the second conductive bus line CBL2 and the third conductive bus line CBL3 are arranged at (e.g., in or on) the same layer (e.g., on the first gate insulating layer 203 of FIG. 7B) as that of the first gate electrode of the first transistor and/or a first electrode of the storage capacitor. The first conductive bus line CBL1 is arranged at (e.g., in or on) the same layer (e.g., on the first interlayer insulating layer 205 of FIG. 7B) as that of a second electrode of the storage capacitor and/or a lower gate electrode of the third gate electrode of the third transistor. In another embodiment, any one selected from among the first conductive bus line CBL1, the second conductive bus line CBL2, and the third conductive bus line CBL3 may be arranged at (e.g., in or on) the same layer (e.g., on the second gate insulating layer 209 of FIG. 7B) as that of an upper gate electrode of the third gate electrode.

FIG. 10 shows conductive bus lines (e.g., the first conductive bus line CBL1 and the second conductive bus line CBL2), which are disposed at (e.g., in or on) different layers from each other, are spaced apart from each other in a direction (e.g., the y direction in FIG. 10) that is parallel to or substantially parallel to the upper surface of the substrate 100, and do not overlap with each other. In another embodiment, the first conductive bus line CBL1 and the second conductive bus line CBL2 disposed at (e.g., in or on) different layers from each other may overlap with each other at (e.g., in or on) the second display area DA2.

Referring again to FIG. 9, the first conductive bus line CBL1 may extend to pass the second display area DA2, and the first conductive bus line CBL1 may be electrically connected to the first electrode 221 of the second red light-emitting diode ED2r by a conductive layer CM and the first conductive pattern layer CMP1.

Referring to FIGS. 9 and 11, the first conductive bus line CBL1 may be electrically connected to the conductive layer CM disposed on the first conductive bus line CBL1. The conductive layer CM may contact the first conductive bus line CBL1 through a contact hole GCNT penetrating at least one insulating layer (e.g., the second interlayer insulating layer 207, the second gate insulating layer 209, and the third interlayer insulating layer 210), which is arranged between the first conductive bus line CBL1 and the conductive layer CM. In some embodiments, the conductive layer CM may be a medium layer electrically connecting the first conductive bus line CBL1 to the first electrode 221 of the second red light-emitting diode ED2r, and may be a portion of the first connection line PWL1 described above with reference to FIG. 7A.

The first conductive pattern layer CMP1 may be arranged between the first organic insulating layer 211 and the second organic insulating layer 213. The first conductive pattern layer CMP1 may contact the conductive layer CM through a contact hole SCNT penetrating the first organic insulating layer 211.

The first electrode 221 of the second red light-emitting diode ED2r may be disposed on the second organic insulating layer 213, and may be electrically connected to the first conductive pattern layer CMP1 through a first via contact hole VCNT1 penetrating the second organic insulating layer 213. The first electrode 221 of the second red light-emitting diode ED2r may overlap with the opening 215OP1 of the bank layer 215. The first functional layer 222a, the emission layer 222b, the second functional layer 222c, and the second electrode 223 may be disposed above the first electrode 221 through the opening 215OP1 of the bank layer 215.

The conductive lines VBL that are patterned portions of the first conductive pattern layer CMP1 may be disposed under the first electrode 221 of the second red light-emitting diode ED2r, as described above. The conductive lines VBL may overlap with the opening 215OP1 of the bank layer 215 that corresponds to the emission area of the second red light-emitting diode ED2r.

Referring to FIG. 9, the second conductive bus line CBL2 may extend to pass the second display area DA2, and may be electrically connected to the first electrode 221 of the second green light-emitting diode ED2g by the conductive layer CM and the second conductive pattern layer CMP2.

Referring to FIGS. 9 and 12, the second conductive bus line CBL2 may be electrically connected to the conductive layer CM disposed on the second conductive bus line CBL2. The conductive layer CM may contact the second conductive bus line CBL2 through a contact hole GCNT penetrating at least one insulating layer (e.g., the first interlayer insulating layer 205, the second interlayer insulating layer 207, the second gate insulating layer 209, and the third interlayer insulating layer 210), which is arranged between the second conductive bus line CBL2 and the conductive layer CM.

The second conductive pattern layer CMP2 may be arranged between the first organic insulating layer 211 and the second organic insulating layer 213. The second conductive pattern layer CMP2 may contact the conductive layer CM through the contact hole SCNT penetrating the first organic insulating layer 211.

The first electrode 221 of the second green light-emitting diode ED2g may be disposed on the second organic insulating layer 213, and may be electrically connected to the second conductive pattern layer CMP2 through a second via contact hole VCNT2 penetrating the second organic insulating layer 213. The first electrode 221 of the second green light-emitting diode ED2g may overlap with the opening 215OP2 of the bank layer 215. The first functional layer 222a, the emission layer 222b, the second functional layer 222c, and the second electrode 223 may be disposed above the first electrode 221 through the opening 215OP2 of the bank layer 215.

The second conductive pattern layer CMP2 may be disposed under the first electrode 221 of the second green light-emitting diode ED2g, as described above.

In the second display area DA2, two second green light-emitting diodes ED2g may be electrically connected to each other by the second connection line PWL2. In an embodiment, FIG. 12 shows that the second connection line PWL2 is disposed on the second organic insulating layer 213. The second connection line PWL2 may be integrally connected to the first electrode 221 of each second green light-emitting diode ED2g. The second connection line PWL2 may include the same material as that of the first electrode 221 of each second green light-emitting diode ED2g. For example, when the first electrode 221 has a three-layered structure including an ITO layer, an Ag layer, and an ITO layer, the second connection line PWL2 may also have the three-layered structure including the ITO layer, the Ag layer, and the ITO layer. In another embodiment, the second connection line PWL2 may include (e.g., may be) any one of the layers forming the first electrode 221. For example, when the first electrode 221 has the three-layered structure including the ITO layer, the Ag layer, and the ITO layer, the second connection line PWL2 may have a single-layer structure including an ITO layer.

Some portions of the second conductive pattern layer CMP2 may overlap with an emission area of each of the second green light-emitting diode ED2g (e.g., the opening 215OP2 of the bank layer 215). In a plane (e.g., in a plan view), the second conductive pattern layer CMP2 may overlap with the second connection line PWL2 and the first electrodes 221 of two second green light-emitting diodes ED2g that are integrally connected to each other.

The third conductive bus line CBL3 may extend to pass the second display area DA2, and the third conductive bus line CBL3 may be electrically connected to the first electrode 221 of the second blue light-emitting diode ED2b by the conductive layer CM and the third conductive pattern layer CMP3. An electrical connection structure of the conductive layer CM, the third conductive pattern layer CMP3, and the first electrode 221 of the second blue light-emitting diode ED2b may be the same or substantially the same as that described above with reference to FIG. 11. The conductive layer CM, which electrically connects the third conductive bus line CBL3 to the third conductive pattern layer CMP3, may be a portion of the third connection line PWL3, and the first electrode 221 of the second blue light-emitting diode ED2b may contact the third conductive pattern layer CMP3 through a third via contact hole VCNT3 penetrating the second organic insulating layer 213 (e.g., see FIG. 11).

Referring to FIGS. 8 and 9, in the first display area DA1 and the second display area DA2, first via contact holes VCNT1 and VCNT1′ and third via contact holes VCNT3 and VCNT3′ may be located in a virtual straight line extending in the first direction (e.g., the x direction). A second via contact hole VCNT2′ formed in the second organic insulating layer to electrically connect the first electrode 221 of the first green light-emitting diode ED1g to the first sub-pixel circuit PC1 may not be in the same virtual straight line as that of the first via contact hole VCNT1′ and the third via contact hole VCNT3′ in the first display area DA1. Similarly, a second via contact hole VCNT2 formed in the second organic insulating layer to electrically connect the first electrode 221 of the second green light-emitting diode ED2g to the second conductive pattern layer CMP2 may not be in the same virtual straight line as that of the first via contact hole VCNT1 and the third via contact hole VCNT3 in the second display area DA2. The first via contact holes VCNT1 and VCNT1′, the second via contact holes VCNT2 and VCNT2′, and the third via contact holes VCNT3 and VCNT3′ formed in the second organic insulating layer may overlap with and may be covered by the bank layer 215 (e.g., see FIGS. 6B and 7B) like the via contact hole VCNT shown in FIGS. 6B and 7B.

The first electrode 221 of the first red light-emitting diode ED1r arranged at (e.g., in or on) the first display area DA1 may contact the first sub-pixel circuit through the first via contact hole VCNT1′ formed in the second organic insulating layer. The first electrode 221 of the first blue light-emitting diode ED1b may contact the first sub-pixel circuit through the third via contact hole VCNT3′ formed in the second organic insulating layer.

In a plane (e.g., in a plan view), a location of the first via contact hole VCNT1′ with In a plane (e.g., in a plan view), a location of the first via contact hole VCNT1′ with respect to the first electrode 221 of the first red light-emitting diode ED1r may be the same or substantially the same as a location of the first via contact hole VCNT1 with respect to the first electrode 221 of the second red light-emitting diode ED2r. For example, an angle (e.g., a of FIG. 8) between a virtual reference line IL extending in the second direction (e.g., the y direction) and a first virtual line IL1 connecting the first via contact hole VCNT1′ from the center C of the emission area of the first red light-emitting diode ED1r may be the same or substantially the same as an angle (e.g., β of FIG. 9) between the virtual reference line IL extending in the second direction (e.g., the y direction) and a second virtual line IL2 connecting the first via contact hole VCNT1 from the center C of the emission area of the second red light-emitting diode ED2r. Here, the center C of the emission area of the first red light-emitting diode ED1r indicates the center of the opening 215OP1 of the bank layer that corresponds to the first red light-emitting diode ED1r, and the center C of the emission area of the second red light-emitting diode ED2r indicates the center of the opening 215OP1 of the bank layer that corresponds to the second red light-emitting diode ED2r.

Similarly, in a plane (e.g., in a plan view), a location of the third via contact hole VCNT3′ with respect to the first electrode 221 of the first blue light-emitting diode ED1b may be the same or substantially the same as a location of the third via contact hole VCNT3 with respect to the first electrode 221 of the second blue light-emitting diode ED2b.

Therefore, it may be possible to prevent or substantially prevent light from the first light-emitting diode ED1 and light from the second light-emitting diode ED2 from being differently recognized by a user, or reduce such recognition, and it may also be possible to prevent or substantially prevent the second display area DA2 from being noticeably viewed, or reduce such viewing.

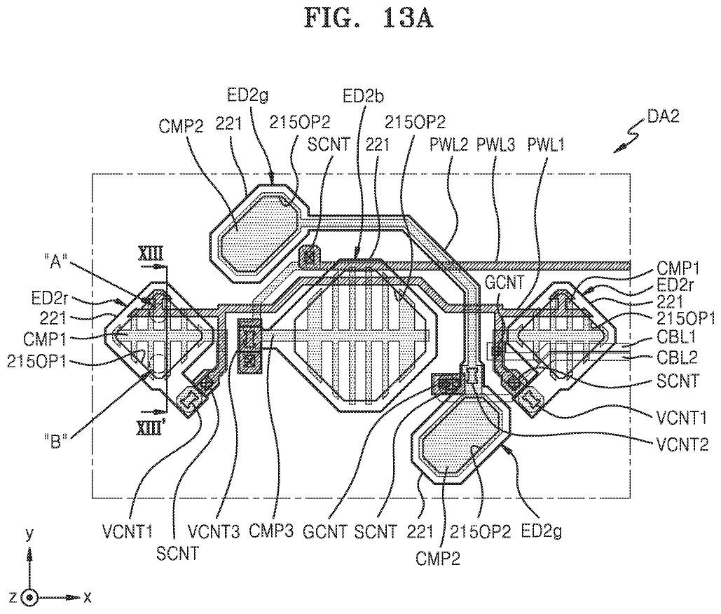

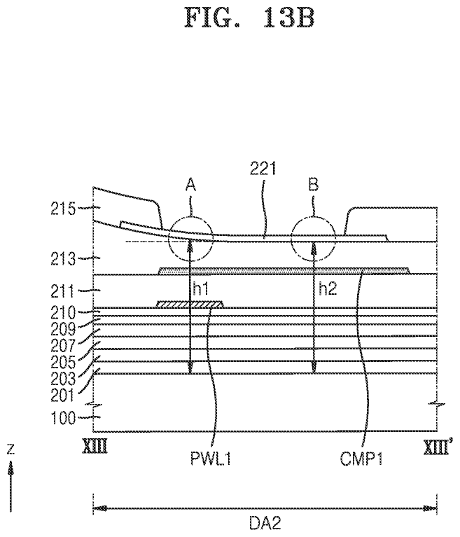

FIG. 13A is a plan view of a second display area of a display panel, according to an embodiment. FIG. 13B is a cross-sectional view of the second display area taken along the line XIII-XIII′ of FIG. 13A.

The first electrode 221 of each of the second red light-emitting diode ED2r, the second green light-emitting diode ED2g, and the second blue light-emitting diode ED2b, which are arranged at (e.g., in or on) the second display area DA2 of FIG. 13A, the openings 215OP1, 215OP2, and 215OP3 of the bank layer, the first conductive pattern layer CMP1 to the third conductive pattern layer CMP3, and the first conductive bus line CBL1 and the second conductive bus line CBL2 are the same or substantially the same as those described above with reference to FIGS. 9, 11, and 12, and thus, redundant description thereof may not be repeated. Structures of the contact holes SCNT and GCNT and the first via contact hole VCNT1 to the third via contact hole VCNT3 are the same or substantially the same as those described above with reference to FIG. 11, and thus, hereinafter, their differences are mainly described in more detail for convenience.

Referring to FIG. 13A, the first conductive pattern layer CMP1 and the third conductive pattern layer CMP3 are disposed under the first electrodes 221 of the second red light-emitting diode ED2r and the second blue light-emitting diode ED2b, respectively. A conductive line (e.g., the first connection line PWL1) may be disposed under the first conductive pattern layer CMP1 and the third conductive pattern layer CMP3.

As described above with reference to FIG. 11, the first connection line PWL1 may be disposed on the third interlayer insulating layer 210. The first connection line PWL1 may overlap with a portion of the first electrode 221 of the second red light-emitting diode ED2r and/or a portion of the first electrode 221 of the second blue light-emitting diode ED2b. The first connection line PWL1 may overlap with the opening 215OP1 of the bank layer that corresponds to the emission area of the second red light-emitting diode ED2r and/or the opening 215OP3 of the bank layer that corresponds to the emission area of the second blue light-emitting diode ED2b.

As the first connection line PWL1 is further disposed under the first conductive pattern layer CMP1 and the third conductive pattern layer CMP3, a partial height of the first electrode 221 may be adjusted. Referring to FIGS. 13A and 13B, a vertical distance h1 from the upper surface of the substrate 100 to an upper portion A of the first electrode 221 extending in the z direction (e.g., a vertical distance from the upper surface of the substrate 100 to a lower surface of the upper portion A of the first electrode 221) may be greater than a vertical distance h2 from the upper surface of the substrate 100 to a lower portion B of the first electrode 221 extending in the z direction (e.g., a vertical distance from the upper surface of the substrate 100 to a lower surface of the lower portion B of the first electrode 221).

In some embodiments, when a height of the first electrode of the first red light-emitting diode at (e.g., in or on) the first display area (e.g., a height of the first electrode from the upper surface of the substrate in the z direction) is partially different, the partial height of the first electrode of the first red light-emitting diode (e.g., a height of a portion A and a height of a portion B) may be changed by using the first connection line PWL1, as described with reference to FIGS. 13A and 13B. As described, when the height of the first electrode of the first blue light-emitting diode at (e.g., in or on) the first display area (e.g., the height of the first electrode from the upper surface of the substrate in the z direction) is partially different, the partial height of the first electrode of the first blue light-emitting diode may be changed by using the first connection line PWL1.

The third connection line PWL3 may be arranged at (e.g., in or on) the same layer (e.g., on the third interlayer insulating layer) as that of the first connection line PWL1. FIG. 13A shows that the first connection line PWL1, which is selected from among the first connection line PWL1 and the third connection line PWL3, overlaps with the first electrode 221 of the second red light-emitting diode ED2r and/or the first electrode 221 of the second blue light-emitting diode ED2b, but the present disclosure is not limited thereto. In other embodiments, the third connection line PWL3 may overlap with the first electrode 221 of the second red light-emitting diode ED2r and/or the first electrode 221 of the second blue light-emitting diode ED2b. In other embodiments, the first connection line PWL1 and the third connection line PWL3 may overlap with the first electrode 221 of the second red light-emitting diode ED2r and/or the first electrode 221 of the second blue light-emitting diode ED2b.

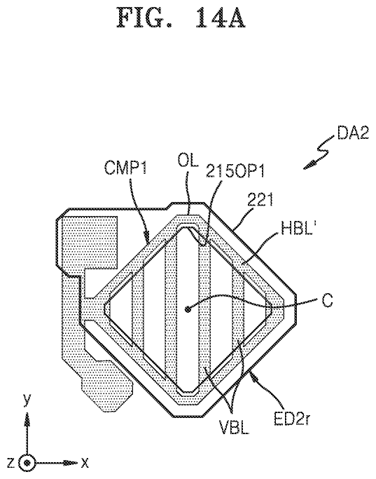

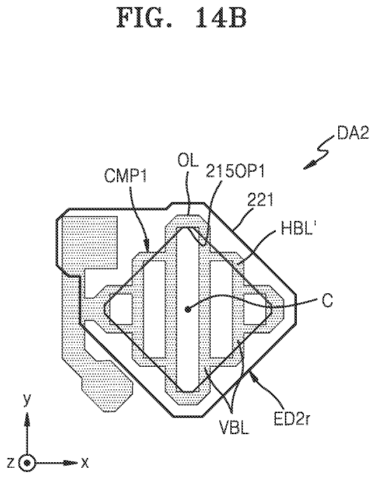

FIGS. 14A and 14B are schematic plan views of a first conductive pattern layer and a third conductive pattern layer, according to one or more embodiments. The conductive lines VBL extending in the second direction (e.g., the y direction) of the first conductive pattern layer CMP1 shown in FIGS. 9 and 13A are connected to each other by the connection conductive line HBL passing the first electrode 221 or the center C of the opening 2150P of the bank layer, but the present disclosure is not limited thereto.

In other embodiments, as shown in FIGS. 14A and 14B, the conductive lines VBL of the first conductive pattern layer CMP1 at (e.g., in or on) the second display area DA2 may be spaced apart from each other, and may be connected to each other by a connection conductive line HBL′ that is relatively farther from the first electrode 221 or the center C of the opening 2150P of the bank layer. The conductive lines VBL may be integrally formed with the connection conductive line HBL′. In other words, distal portions of the conductive lines VBL, which are relatively farther from the first electrode 221 or the center C of the opening 2150P of the bank layer, may be physically (e.g., integrally) connected to each other by the connection conductive line HBL′.

An outer line OL of the connection conductive line HBL′ may be relatively even as shown in FIG. 14A, or may be stepwisely bent in a plane as shown in FIG. 14B. In some embodiments, as shown in FIG. 14A, the connection conductive line HBL′ may not overlap with the opening 215OP1 of the bank layer. In other embodiments, as shown in FIG. 14B, the connection conductive line HBL′ may overlap with the opening 215OP1 of the bank layer.

According to the embodiments described above with reference to FIGS. 8 and 9, the connection conductive line HBL of each of the first conductive pattern layer CMP1 and the third conductive pattern layer CMP3 extends to pass the center C of the emission area, and overlaps with the emission area. In this case, in the plane (e.g., in a plan view), a shape in which the opening 215OP1 of the bank layer that corresponds to the second red light-emitting diode ED2r (e.g., see FIG. 9) overlaps with the first conductive pattern layer CMP1 may be different from a shape in which the opening 215OP1 of the bank layer that corresponds to the first red light-emitting diode ED1r (e.g., see FIG. 8) overlaps with at least one line (e.g., data lines and driving power lines). As described, a shape in which the opening 215OP3 of the bank layer that corresponds to the second blue light-emitting diode ED2b (e.g., see FIG. 9) overlaps with the third conductive pattern layer CMP3 may be different from a shape in which the opening 215OP3 of the bank layer that corresponds to the first blue light-emitting diode ED1b (e.g., see FIG. 8) overlaps with at least one line (e.g., the data lines and the driving power lines).

According to the embodiment shown in FIG. 14A, when the connection conductive line HBL′ of the first conductive pattern layer CMP1 does not overlap with the emission area, the shape in which the opening 215OP1 of the bank layer that corresponds to the second red light-emitting diode ED2r overlaps with the first conductive pattern layer CMP1 may be the same or substantially the same as the shape in which the opening 215OP1 of the bank layer that corresponds to the first red light-emitting diode ED1r (e.g., see FIG. 8) overlaps with at least one line (e.g., the data lines and the driving power lines) in the plane (e.g., in a plan view).

FIGS. 14A and 14B show the first conductive pattern layer CMP1 overlaps with the second red light-emitting diode ED2r, but the present disclosure is not limited thereto. The third conductive pattern layer CMP3 (e.g., see FIGS. 9 and 13A) overlapping with the third blue light-emitting diode ED2b may have the same or substantially the same characteristics as those of the first conductive pattern layer CMP1 by referring to FIGS. 14A and 14B. For example, a connection conductive line connecting the conductive lines of the third conductive pattern layer CMP3 (e.g., see FIGS. 9 and 13A) may not overlap with the emission area. In this case, the shape in which the opening 215OP3 of the bank layer that corresponds to the second blue light-emitting diode ED2b overlaps with the third conductive pattern layer CMP3 may be the same or substantially the same as the shape in which the opening 215OP3 of the bank layer that corresponds to the first blue light-emitting diode ED1b overlaps with at least one line (e.g., the data lines and the driving power lines).

According to one or more embodiments of the present disclosure, an area of a transmission area of a second display area including the transmission area may be sufficiently secured, and the second display area may be prevent from distinguishing from a first display area. Accordingly, the second display area may not be viewed by a user. However, the aspects and features of the present disclosure are not limited thereto.

Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display panel comprising:
a first sub-pixel circuit at a first display area, and comprising:
a first transistor comprising a first semiconductor layer and a first gate electrode;
a storage capacitor; and
a second transistor comprising a second semiconductor layer and a second gate electrode;
an organic insulating layer on the first transistor and the second transistor;
a first light-emitting diode at the first display area, and electrically connected to the first sub-pixel circuit, the first light-emitting diode comprising a first electrode on the organic insulating layer;
a second light-emitting diode at a second display area at least partially surrounded by the first display area, and comprising a first electrode on the organic insulating layer, the second display area comprising a transmission area;
a bank layer having a first opening overlapping with the first electrode of the first light-emitting diode, and a second opening overlapping with the first electrode of the second light-emitting diode;
at least one line overlapping with the first electrode of the first light-emitting diode and the first opening of the bank layer; and
a conductive pattern layer at the second display area and overlapping with the first electrode of the second light-emitting diode and the second opening of the bank layer,
wherein the at least one line comprises at least one of a driving power line, a data connection line, or a data line, and
wherein the conductive pattern layer is located at a same layer as that of the at least one line.

2. The display panel of claim 1, further comprising a lower organic insulating layer under the organic insulating layer,
wherein the conductive pattern layer and the at least one line are located between the lower organic insulating layer and the organic insulating layer.

3. The display panel of claim 1, further comprising:
a second sub-pixel circuit at a third display area between the first display area and the second display area, and electrically connected to the second light-emitting diode; and
a conductive bus line extending towards the second display area at the third display area to electrically connect the second sub-pixel circuit to the second light-emitting diode.

4. The display panel of claim 3, wherein the conductive bus line is located at a same layer as that of any one of the first gate electrode, an electrode of the storage capacitor, or the second gate electrode.

5. The display panel of claim 1, wherein the conductive pattern layer comprises a plurality of conductive lines overlapping with the second opening of the bank layer, and
wherein an extension direction of each of the plurality of conductive lines is the same as an extension direction of the at least one line overlapping with the first opening of the bank layer.

6. The display panel of claim 5, wherein the at least one line comprises a plurality of data lines, and a data connection line, and
wherein a first distance between two adjacent conductive lines selected from among the plurality of conductive lines is the same as a second distance between two adjacent lines selected from among the plurality of data lines and the data connection line.

7. The display panel of claim 5, wherein the plurality of conductive lines are integrally coupled to a connection conductive line crossing the plurality of conductive lines.

8. The display panel of claim 1, wherein the at least one line comprises a connection portion of a plurality of driving power lines that are physically connected to each other, and
wherein a shape or an area in which the second opening of the bank layer overlaps with the conductive pattern layer is the same as a shape or an area in which the first opening of the bank layer overlaps with the connection portion of the plurality of driving power lines.

9. The display panel of claim 1, wherein, in a plan view, a shape in which the second opening of the bank layer overlaps with the conductive pattern layer is the same as a shape in which the first opening of the bank layer overlaps with a portion of the at least one line.

10. The display panel of claim 1, further comprising a conductive line at the second display area,
wherein the conductive line overlaps with each of the first electrode of the second light-emitting diode, the second opening of the bank layer, and the conductive pattern layer.

11. The display panel of claim 10, further comprising an additional second light-emitting diode at the second display area, and configured to emit the same color of light as that of the second light-emitting diode,
wherein the conductive line comprises a connection line electrically connecting the second light-emitting diode to the additional second light-emitting diode.

12. The display panel of claim 1, wherein the organic insulating layer has a first via contact hole for electrically connecting the first sub-pixel circuit to the first electrode of the first light-emitting diode, and a second via contact hole for electrically connecting the conductive pattern layer to the first electrode of the second light-emitting diode, and
wherein each of the first via contact hole and the second via contact hole overlaps with the bank layer.

13. The display panel of claim 12, wherein an angle between a first virtual line extending from a center of the first opening of the bank layer towards the first via contact hole and a virtual reference line passing the center of the first opening in a first direction is the same as an angle between a second virtual line extending from a center of the second opening of the bank layer towards the second via contact hole and a virtual reference line passing the center of the second opening in the first direction.

14. An electronic apparatus comprising:
a display panel comprising:
a first display area; and
a second display area at least partially surrounded by the first display area, and comprising a transmission area; and
a component under the display panel, and corresponding to the second display area,
wherein the display panel comprises:
a first sub-pixel circuit at the first display area, and comprising:
a first transistor comprising a first semiconductor layer and a first gate electrode;
a storage capacitor; and
a second transistor comprising a second semiconductor layer and
a second gate electrode;
an organic insulating layer above the first transistor and the second transistor;
a first light-emitting diode at the first display area, and electrically connected to the first sub-pixel circuit, the first light-emitting diode comprising a first electrode on the organic insulating layer;
a second light-emitting diode at the second display area, and comprising a first electrode on the organic insulating layer;
a bank layer having a first opening overlapping with the first electrode of the first light-emitting diode, and a second opening overlapping with the first electrode of the second light-emitting diode;
at least one line overlapping with the first electrode of the first light-emitting diode and the first opening of the bank layer; and
a conductive pattern layer at the second display area, and overlapping with the first electrode of the second light-emitting diode and the second opening of the bank layer,
wherein the at least one line comprises at least one of a driving power line, a data connection line, or a data line, and
wherein the conductive pattern layer is located at a same layer as that of the at least one line.

15. The electronic apparatus of claim 14, wherein the component comprises a camera or a sensor.

16. The electronic apparatus of claim 14, wherein the display panel further comprises a lower organic insulating layer under the organic insulating layer, and
wherein the conductive pattern layer and the at least one line are located between the lower organic insulating layer and the organic insulating layer.

17. The electronic apparatus of claim 14, wherein the display panel further comprises:
a second sub-pixel circuit at a third display area between the first display area and the second display area, and electrically connected to the second light-emitting diode; and
a conductive bus line extending towards the second display area at the third display area to electrically connect the second sub-pixel circuit to the second light-emitting diode.

18. The electronic apparatus of claim 17, wherein the conductive bus line is located at a same layer as that of any one of the first gate electrode, an electrode of the storage capacitor, or the second gate electrode.

19. The electronic apparatus of claim 14, wherein the conductive pattern layer comprises a plurality of conductive lines overlapping with the second opening of the bank layer, and
wherein an extension direction of each of the plurality of conductive lines is the same as an extension direction of the at least one line overlapping with the first opening of the bank layer.

20. The electronic apparatus of claim 19, wherein the at least one line of the display panel comprises a plurality of data lines and data connection lines, and
wherein a first distance between two adjacent conductive lines selected from among the plurality of conductive lines is the same as a second distance between two adjacent lines selected from among the plurality of data lines and data connection lines.

21. The electronic apparatus of claim 19, wherein the plurality of conductive lines are integrally connected to a connection conductive line crossing the plurality of conductive lines.

22. The electronic apparatus of claim 14, wherein the at least one line comprises a connection portion of a plurality of driving power lines that are physically connected to each other, and
wherein a shape or an area in which the second opening of the bank layer overlaps with the conductive pattern layer is the same as a shape or an area in which the first opening of the bank layer overlaps with the connection portion of the plurality of driving power lines.

23. The electronic apparatus of claim 14, wherein, in a plan view, a shape in which the second opening of the bank layer overlaps with the conductive pattern layer is the same as a shape in which the first opening of the bank layer overlaps with a portion of the at least one line.

24. The electronic apparatus of claim 14, wherein the display panel further comprises a conductive line at the second display area, and
wherein the conductive line overlaps with each of the first electrode of the second light-emitting diode, the second opening of the bank layer, and the conductive pattern layer.

25. The electronic apparatus of claim 24, wherein the display panel further comprises an additional second light-emitting diode at the second display area, and configured to emit the same color of light as that of the second light-emitting diode, and
wherein the conductive line comprises a connection line electrically connecting the second light-emitting diode to the additional second light-emitting diode.

26. The electronic apparatus of claim 14, wherein the organic insulating layer has a first via contact hole for electrically connecting the first sub-pixel circuit to the first electrode of the first light-emitting diode, and a second via contact hole for electrically connecting the conductive pattern layer to the first electrode of the second light-emitting diode, and
wherein an angle between a first virtual line extending from a center of the first opening of the bank layer towards the first via contact hole and a virtual reference line passing the center of the first opening in a first direction is the same as an angle between a second virtual line extending from a center of the second opening of the bank layer towards the second via contact hole and a virtual reference line passing the center of the second opening in the first direction.
